(19) United States
(12) Patent Application Publication
(10) Pub. No.: US 2026/0013219 A1
(43) Pub. Date: Jan. 8, 2026

(54) SEMICONDUCTOR DEVICE

(71) Applicant: SAMSUNG ELECTRONICS CO., LTD., Suwon-si (KR)

(72) Inventors: Kyuman Hwang, Suwon-si (KR); Sungil Park, Suwon-si (KR)

(21) Appl. No.: 19/009,822

(22) Filed: Jan. 3, 2025

(30) Foreign Application Priority Data
Jul. 3, 2024 (KR) 10-2024-0087532

(51) Int. Cl. H10D 84/85; H10D 84/01

(52) U.S. Cl. CPC H10D 84/852; H10D 84/0167; H10D 84/0188; H10D 84/856

(57) ABSTRACT

A semiconductor device includes: a substrate; a first active pattern including a first lower pattern and a first sheet pattern; a second active pattern spaced apart from the first active pattern in a first direction and including a second lower pattern and a second sheet pattern; a first gate electrode disposed on the first active pattern and elongated in the first direction; a second gate electrode disposed on the second active pattern and elongated in the first direction; a gate isolation insulating film disposed between the first and second gate electrodes and elongated in a second direction; and a blocking spacer disposed between the gate isolation insulating film and the first gate electrode, the blocking spacer disposed on a side surface of the first sheet pattern and the first lower pattern and elongated in a third direction perpendicular to an upper surface of the substrate.

### CROSS-REFERENCE TO RELATED APPLICATION

This application claims priority to Korean Patent Application No. 10-2024-0087532, filed in the Korean Intellectual Property Office on Jul. 3, 2024, the entire contents of which are hereby incorporated by reference.

### BACKGROUND

A semiconductor device is a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

As the industry develops, the performance and functional demands of the electronic devices are also increasing. The degree of integration of the semiconductor devices is increasing to meet these demands on high performance characteristics.

### SUMMARY

The present disclosure provides a semiconductor device having, in some implementations, improved reliability and integration compared to a conventional semiconductor device.

Within a semiconductor device, a blocking spacer can be disposed on a sheet pattern, protecting the sheet pattern. Accordingly, the reliability of the semiconductor device can be improved. In some implementations, the blocking spacer is disposed on a side surface of the sheet pattern, resulting in improved integration density of the semiconductor device.

In a first general aspect, a semiconductor device includes: a substrate, a first active pattern disposed on the substrate, wherein the first active pattern includes a first lower pattern and a first sheet pattern disposed on the first lower pattern, a second active pattern disposed on the substrate and spaced apart from the first active pattern in a first direction, wherein the second active pattern includes a second lower pattern and a second sheet pattern disposed on the second lower pattern, a first gate electrode disposed on the first active pattern and extending in the first direction, a second gate electrode disposed on the second active pattern and extending in the first direction, a gate isolation insulating film disposed between the first gate electrode and the second gate electrode and extending in a second direction different from the first direction, and a blocking spacer disposed between the gate isolation insulating film and the first gate electrode, wherein the blocking spacer is disposed on a side surface of the first sheet pattern and a side surface of the first lower pattern, and extends in a third direction perpendicular to an upper surface of the substrate.

In a second general aspect, a semiconductor device includes: a substrate, a first active pattern disposed on the substrate and including a first sheet pattern, a second active pattern disposed to be spaced apart from the first active pattern in a first direction and including a second sheet pattern, a third active pattern disposed on the first active pattern and including a third sheet pattern, a fourth active pattern disposed on the second active pattern and including a fourth sheet pattern, a first gate electrode surrounding at least a portion of the first sheet pattern and extending in the first direction, a second gate electrode surrounding at least a portion of the second sheet pattern and extending in the first direction, a third gate electrode disposed on the first gate electrode and surrounding at least a portion of the third sheet pattern, a fourth gate electrode disposed on the second gate electrode and surrounding at least a portion of the fourth sheet pattern, a gate capping pattern disposed on the third gate electrode and the fourth gate electrode, a gate isolation insulating film disposed between the first gate electrode and the second gate electrode and between the third gate electrode and the fourth gate electrode, and a first blocking spacer disposed between the gate isolation insulating film and the first gate electrode and between the gate isolation insulating film and the third gate electrode, wherein the gate isolation insulating film extends in a second direction different from the first direction, and the first blocking spacer is in contact with a side surface of the first sheet pattern and a side surface of the third sheet pattern, respectively.

In a third general aspect, a semiconductor device includes: a substrate, a first active pattern disposed on the substrate, wherein the first active pattern includes a first lower pattern and a first sheet pattern disposed on the first lower pattern, a second active pattern disposed on the substrate and spaced apart from the first active pattern in a first direction, wherein the second active pattern includes a second lower pattern and a second sheet pattern disposed on the second lower pattern, a third active pattern disposed on the first active pattern and including a third sheet pattern, a fourth active pattern disposed on the second active pattern and including a fourth sheet pattern, a first gate electrode surrounding at least a portion of the first sheet pattern and extending in the first direction, a second gate electrode surrounding at least a portion of the second sheet pattern and extending in the first direction, a third gate electrode disposed on the first gate electrode and surrounding at least a portion of the third sheet pattern, a fourth gate electrode disposed on the second gate electrode and surrounding at least a portion of the fourth sheet pattern, a gate capping pattern disposed on the third gate electrode and the fourth gate electrode, a first blocking spacer disposed on a side surface of the first lower pattern, a side surface of the first sheet pattern, and a side surface of the third sheet pattern and extending in a second direction different from the first direction, a second blocking spacer disposed on a side surface of the second lower pattern, a side surface of the second sheet pattern, and a side surface of the fourth sheet pattern and extending in the second direction, and a gate isolation insulating film disposed between the first blocking spacer and the second blocking spacer, wherein the gate isolation insulating film includes a stepped portion disposed on an upper surface of the first blocking spacer, and a bottom surface of the gate isolation insulating film is disposed on an upper surface of the substrate.

### BRIEF DESCRIPTION OF THE DRAWINGS

FIG. 1 is a plan view of an example of a semiconductor device.

FIG. 2 is a cross-sectional view taken along line A-A of FIG. 1.

FIG. 3 is a cross-sectional view taken along line B-B of FIG. 1.

FIGS. 4 and 5 are enlarged views of a region Q1 of FIG. 3.

FIG. 6 is a diagram of an example of a semiconductor device.

FIG. 7 is a diagram of an example of a semiconductor device.

FIG. 8 is a diagram of an example of a semiconductor device.

FIG. 9 is a diagram of an example of a semiconductor device.

FIGS. 10 and 11 are diagrams of an example of a semiconductor device.

FIG. 12 is a diagram of an example of a semiconductor device.

FIG. 13 is a diagram of an example of a semiconductor device.

FIG. 14 is a plan view of an example of a semiconductor device.

FIG. 15 is a cross-sectional view taken along line C-C of FIG. 14.

FIG. 16 is a cross-sectional view taken along line D-D of FIG. 14.

FIGS. 17 to 25 are diagrams illustrating intermediate stages, which are part of an example of a method for manufacturing a semiconductor device.

### DETAILED DESCRIPTION

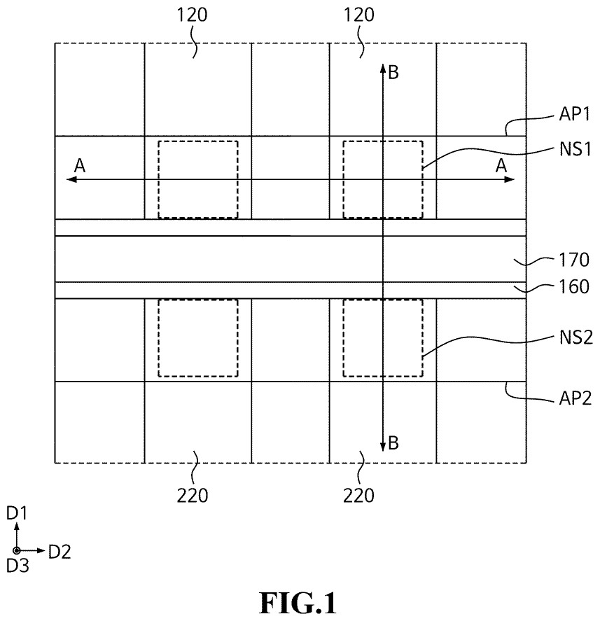

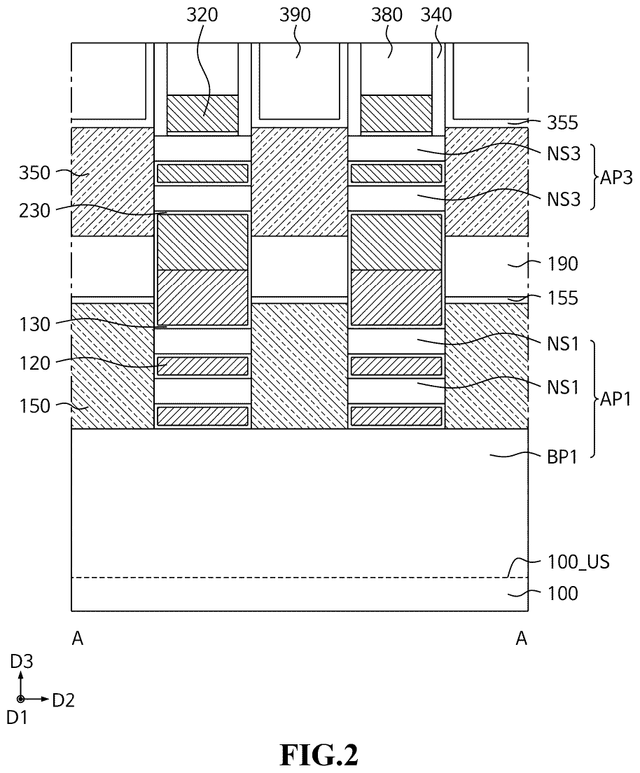

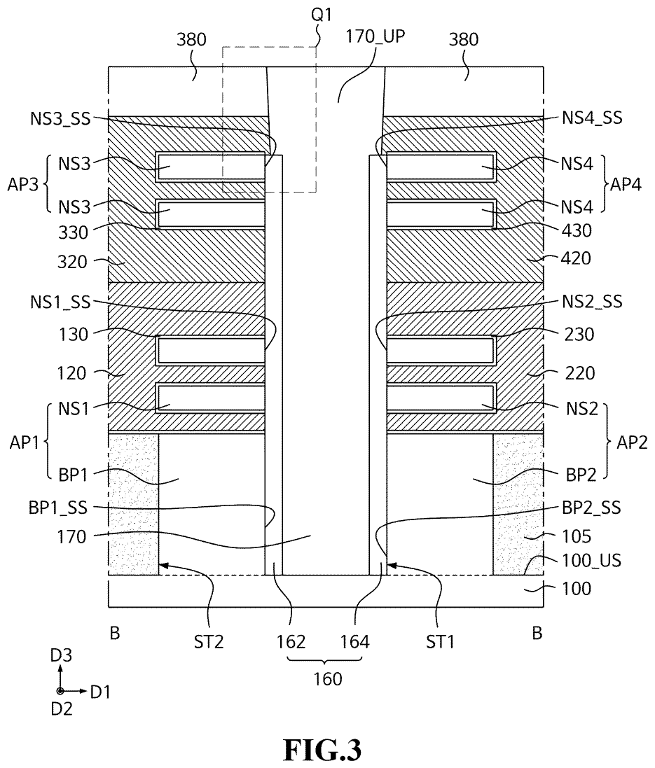

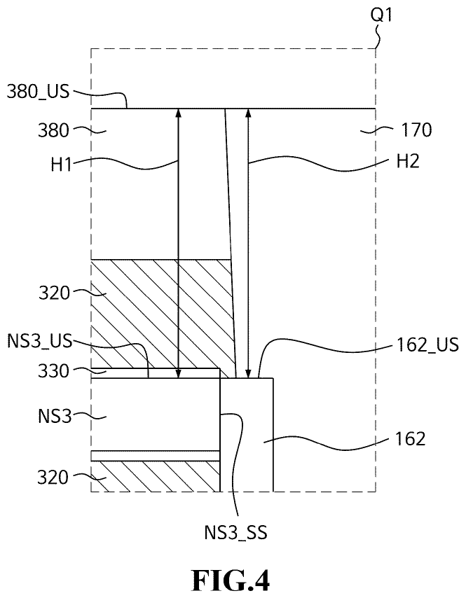

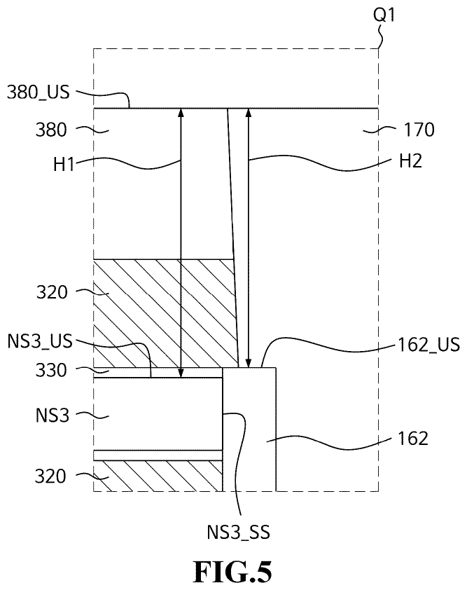

FIG. 1 is a plan view of an example of a semiconductor device. FIG. 2 is a cross-sectional view taken along line A-A of FIG. 1. FIG. 3 is a cross-sectional view taken along line B-B of FIG. 1. FIGS. 4 and 5 are enlarged views of an example of a region Q1 of FIG. 3.

Referring to FIGS. 1 to 5, a semiconductor device includes a substrate 100, first to fourth active patterns AP1, AP2, AP3 and AP4, first to fourth gate electrodes 120, 220, 320 and 420, a blocking spacer 160, a gate isolation insulating film 170, and a gate capping pattern 380.

The substrate 100 may be a bulk silicon or a silicon-on-insulator (SOI). In some implementations, the substrate 100 may include silicon germanium (SiGe), silicon germanium on insulator (SGOI), indium antimony, lead tellurium compound, indium arsenic, indium phosphide, gallium arsenic, or gallium antimony, but the substrate is not limited thereto.

The first active pattern AP1 may be disposed on the substrate 100. The first active pattern AP1 may extend in a second direction D2. The first active pattern AP1 may include a first lower pattern BP1 and a plurality of first sheet patterns NS1. Each of the first and second directions D1 and D2 may be a direction parallel to an upper surface 100_US of the substrate 100.

The plurality of first sheet patterns NS1 may be disposed on the first lower pattern BP1. The plurality of first sheet patterns NS1 may be spaced apart from the first lower pattern BP1 in a third direction D3. Each of the first sheet patterns NS1 may be spaced apart from each other in the third direction D3. The third direction D3 may be a direction intersecting (e.g., perpendicular to) each of the first direction D1 and the second direction D2. The third direction D3 may be a direction perpendicular to the upper surface of the substrate 100. The third direction D3 may be a thickness direction of the substrate 100. A first sheet pattern NS1 may have a nanosheet shape.

The second active pattern AP2 may be disposed on the substrate 100. The second active pattern AP2 may be spaced apart from the first active pattern AP1 in the first direction D1. The second active pattern AP2 may extend in the second direction D2. The second active pattern AP2 may include a second lower pattern BP2 and a plurality of second sheet patterns NS2.

The plurality of second sheet patterns NS2 may be disposed on the second lower pattern BP2. The plurality of second sheet patterns NS2 may be spaced apart from the second lower pattern BP2 in the third direction D3. The second sheet patterns NS2 may be spaced apart from each other in the third direction D3. The second sheet pattern NS2 may have a nanosheet shape.

Each of the first lower pattern BP1 and the second lower pattern BP2 may be formed by etching a portion of the substrate 100. However, the present disclosure is not limited thereto. For example, each of the first lower pattern BP1 and the second lower pattern BP2 may include an epitaxial layer grown from the substrate 100. Each of the first lower pattern BP1 and the second lower pattern BP2 may include an element semiconductor material such as silicon (Si) or germanium (Ge). In addition, each of the first lower pattern BP1 and the second lower pattern BP2 may include a compound semiconductor. For example, the lower pattern BP may include a group IV-IV compound semiconductor or a group III-V compound semiconductor.

For example, the group IV-IV compound semiconductor may be a binary compound or a ternary compound including at least two of carbon (C), silicon (Si), germanium (Ge), and tin (Sn).

For example, the group III-V compound semiconductor may be one of a binary compound, a ternary compound, or a quaternary compound formed by a combination of at least one of aluminum (Al), gallium (Ga), and indium (In) as a group III element and one of phosphorus (P), arsenic (As), and antimony (Sb) as a group V element.

Each of the first sheet pattern NS1 and the second sheet pattern NS2 may include one of an element semiconductor material such as silicon (Si) or silicon germanium (SiGe), a group IV-IV compound semiconductor, or a group III-V compound semiconductor. The first sheet pattern NS1 may include the same material as the first lower pattern BP1 or may include a different material from the first lower pattern BP1. The second sheet pattern NS2 may include the same material as the second lower pattern BP2, or may include a different material from the second lower pattern BP2.

In some implementations, the substrate 100 may include an insulating material. For example, the substrate 100 may be an insulating substrate. A boundary surface between the substrate 100 and the first lower pattern BP1 and a boundary surface between the substrate 100 and the second lower pattern BP2 may be distinguished.

In some implementations, each of the first lower pattern BP1 and the second lower pattern BP2 may include an insulating material. Although not illustrated, the semiconductor device may further include a lower gate contact extending through the first lower pattern BP1 and/or a lower gate contact extending through the second lower pattern BP2.

A first device isolation trench ST1 may be disposed between the first lower pattern BP1 and the second lower pattern BP2. The first device isolation trench ST1 may be defined by the upper surface 100_US of the substrate 100, a side surface BP1_SS of the first lower pattern BP1, and a side surface BP2_SS of the second lower pattern BP2. The blocking spacer 160 and the gate isolation insulating film 170, which will be described below, may be disposed on the first device isolation trench ST1.

A second device isolation trench ST2 may be disposed at one side of the first device isolation trench ST1. The second device isolation trench ST2 may be spaced apart from the first device isolation trench ST1 in the first direction D1. In some implementations, a field insulating film 105 may be disposed on the second device isolation trench ST2. The field insulating film 105 may fill the second device isolation trench ST2.

For example, the field insulating film 105 may include an oxide, a nitride, a nitride oxide, or a combination thereof. Although the field insulating film 105 is illustrated as a single film, the present disclosure is not limited thereto. For example, the field insulating film 105 may be formed of a plurality of films.

The first gate electrode 120 may be disposed on the field insulating film 105 and the first lower pattern BP1. The first gate electrode 120 may extend in the first direction D1. The first gate electrode 120 may intersect the first active pattern AP1. The first gate electrode 120 may be disposed between the plurality of first sheet patterns NS1. The first gate electrode 120 may be disposed between the first sheet pattern NS1 disposed lowermost among the plurality of first sheet patterns NS1, and the first lower pattern BP1. The first gate electrode 120 may surround the first sheet pattern NS1. For example, the first gate electrode 120 may surround three surfaces of the first sheet pattern NS1. The first gate electrode 120 may not be disposed between a side surface NS1_SS of the first sheet pattern NS1 and a first blocking spacer 162.

The second gate electrode 220 may be disposed on the field insulating film 105 and the second lower pattern BP2. The second gate electrode 220 may extend in the first direction D1. The second gate electrode 220 may intersect the second active pattern AP2. The second gate electrode 220 may be disposed between the plurality of second sheet patterns NS2. The second gate electrode 220 may be disposed between the second sheet pattern NS2 disposed lowermost among the plurality of second sheet patterns NS2, and the second lower pattern BP2. The second gate electrode 220 may surround the second sheet pattern NS2. For example, the second gate electrode 220 may surround three surfaces of the second sheet pattern NS2. The second gate electrode 220 may not be disposed between a side surface NS2_SS of the second sheet pattern NS2 and a second blocking spacer 164.

The first gate electrode 120 may overlap the second gate electrode 220 in the first direction D1. The first gate electrode 120 may be spaced apart from the second gate electrode 220 in the first direction D1. The blocking spacer 160 and the gate isolation insulating film 170 may be disposed between the first gate electrode 120 and the second gate electrode 220.

Each of the first gate electrode 120 and the second gate electrode 220 may include at least one of a metal, a metal alloy, a conductive metal nitride, a metal silicide, a doped semiconductor material, a conductive metal oxide, and a conductive metal oxynitride. For example, the first gate electrode 120 and the second gate electrode 220 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto. The conductive metal oxide and the conductive metal oxynitride may include an oxidized form of the material described above, but conductive metal oxide and the conductive metal oxynitride are not limited thereto. In some implementations, the first gate electrode 120 may include the same material as the second gate electrode 220.

Although each of the first gate electrode 120 and the second gate electrode 220 are illustrated as a single film, the present disclosure is not limited thereto. For example, each of the first gate electrode 120 and the second gate electrode 220 may include a work function control film for adjusting a work function and a filling conductive film for filling a space formed by the work function control film. For example, the work function control film may include at least one of titanium nitride (TiN), tantalum nitride (TaN), titanium carbide (TiC), tantalum carbide (TaC), titanium aluminum carbide (TiAlC), or a combination thereof. For example, the filling conductive film may include tungsten (W) or aluminum (Al).

A first gate insulating film 130 may be disposed between the first gate electrode 120 and the first sheet pattern NS1 and between the first gate electrode 120 and the first lower pattern BP1. The first gate insulating film 130 may surround the first sheet pattern NS1. For example, the first gate insulating film 130 may surround three surfaces of the first sheet pattern NS1. The first gate insulating film 130 may not be disposed on the side surface NS1_SS of the first sheet pattern NS1. The first blocking spacer 162 may be disposed on the side surface NS1_SS of the first sheet pattern NS1. The side surface NS1_SS of the first sheet pattern NS1 may be in contact with the first blocking spacer 162.

A second gate insulating film 230 may be disposed between the second gate electrode 220 and the second sheet pattern NS2 and between the second gate electrode 220 and the second lower pattern BP2. The second gate insulating film 230 may surround the second sheet pattern NS2. For example, the second gate insulating film 230 may surround three surfaces of the second sheet pattern NS2. The second gate insulating film 230 may not be disposed on the side surface NS2_SS of the second sheet pattern NS2. The second blocking spacer 164 may be disposed on the side surface NS2_SS of the second sheet pattern NS2. The side surface NS2_SS of the second sheet pattern NS2 may be in contact with the second blocking spacer 164.

Although each of the first gate insulating film 130 and the second gate insulating film 230 is illustrated as a single film, the first gate insulating film 130 and the second gate insulating film 230 may include a plurality of films. For example, each of the first gate insulating film 130 and the second gate insulating film 230 may include an interface insulating film and a high-k insulating film.

The interface insulating film may include silicon oxide. The high-k insulating film may include a high-k material having a greater dielectric constant than the interface insulating film. For example, the high-k insulating film may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

In some implementations, the first gate insulating film 130 and the second gate insulating film 230 may include the same material.

The third active pattern AP3 may be disposed on the first active pattern AP1. The third active pattern AP3 may be disposed to be spaced apart from the first active pattern AP1 in the third direction D3. The third active pattern AP3 may extend in the second direction D2. The third active pattern AP3 may include a plurality of third sheet patterns NS3.

The plurality of third sheet patterns NS3 may be spaced apart from the plurality of first sheet patterns NS1 in the third direction D3. The third sheet patterns NS3 may be spaced apart from each other in the third direction D3. A distance between the first sheet pattern NS1 disposed uppermost and the third sheet pattern NS3 disposed lowermost may be greater than a distance between each of the third sheet patterns NS3. The third sheet pattern NS3 may have a nanosheet shape.

The fourth active pattern AP4 may be disposed on the second active pattern AP2. The fourth active pattern AP4 may be spaced apart from the third active pattern AP3 in the first direction D1. The fourth active pattern AP4 may be disposed to be spaced apart from the second active pattern AP2 in the third direction D3. The fourth active pattern AP4 may extend in the second direction D2. The fourth active pattern AP4 may include a plurality of fourth sheet patterns NS4.

The plurality of fourth sheet patterns NS4 may be spaced apart from the plurality of second sheet patterns NS2 in the third direction D3. The fourth sheet patterns NS4 may be spaced apart from each other in the third direction D3. A distance between the second sheet pattern NS2 disposed uppermost and the fourth sheet pattern NS4 disposed lowermost may be greater than a distance between each of the fourth sheet patterns NS4. The fourth sheet pattern NS4 may have a nanosheet shape.

The description of the material of the third and fourth sheet patterns NS3 and NS4 may be the same as the description of the first and second sheet patterns NS1 and NS2.

The third gate electrode 320 may be disposed on the first gate electrode 120. The third gate electrode 320 may extend in the first direction D1. The third gate electrode 320 may intersect the third active pattern AP3. The third gate electrode 320 may be disposed between the plurality of third sheet patterns NS3. The third gate electrode 320 may surround the third sheet pattern NS3. For example, the third gate electrode 320 may surround three surfaces of the third sheet pattern NS3. The third gate electrode 320 may not be disposed between a side surface NS3_SS of the third sheet pattern NS3 and the first blocking spacer 162. A portion of the third gate electrode 320 may be disposed on an upper surface 162_US of the first blocking spacer 162.

The fourth gate electrode 420 may be disposed on the second gate electrode 220. The fourth gate electrode 420 may extend in the first direction D1. The fourth gate electrode 420 may intersect the fourth active pattern AP4. The fourth gate electrode 420 may be disposed between the plurality of fourth sheet patterns NS4. The fourth gate electrode 420 may surround the fourth sheet pattern NS4. For example, the fourth gate electrode 420 may surround three surfaces of the fourth sheet pattern NS4. The fourth gate electrode 420 may not be disposed between a side surface NS4_SS of the fourth sheet pattern NS4 and the second blocking spacer 164. A portion of the fourth gate electrode 420 may be disposed on an upper surface of the second blocking spacer 164.

The third gate electrode 320 may overlap the fourth gate electrode 420 in the first direction D1. The third gate electrode 320 may be spaced apart from the fourth gate electrode 420 in the first direction D1. The blocking spacer 160 and the gate isolation insulating film 170 may be disposed between the third gate electrode 320 and the fourth gate electrode 420.

The description of the materials of the third and fourth gate electrodes 320 and 420 may be the same as the description of the first and second gate electrodes 120 and 220.

Although each of the third gate electrode 320 and the fourth gate electrode 420 is illustrated as a single film, the present disclosure is not limited thereto. For example, each of the third gate electrode 320 and the fourth gate electrode 420 may include a work function control film for adjusting a work function and a filling conductive film that fills the space formed by the work function control film.

In some implementations, the work function control film of the first gate electrode 120 and the work function control film of the third gate electrode 320 may include different materials. The work function control film of the first gate electrode 120 may include a P-type work function control film, and the work function control film of the third gate electrode 320 may include an N-type work function control film. In another aspect, the work function control film of the first gate electrode 120 may include an N-type work function control film, and the work function control film of the third gate electrode 320 may include a P-type work function control film. Likewise, the work function control film of the second gate electrode 220 and the work function control film of the fourth gate electrode 420 may also include different materials.

In some implementations, the third gate electrode 320 and the fourth gate electrode 420 may include the same material. For example, the work function control film of the third gate electrode 320 and the work function control film of the fourth gate electrode 420 may include the same material.

In some implementations, a boundary surface between the first gate electrode 120 and the third gate electrode 320 may be distinguished, e.g., the first gate electrode 120 and the third gate electrode 320 are made of different materials. Likewise, a boundary surface between the second gate electrode 220 and the fourth gate electrode 420 may be distinguished. An upper surface of the first gate electrode 120 and a lower surface of the third gate electrode 320 may be in contact with each other. An upper surface of the second gate electrode 220 and a lower surface of the fourth gate electrode 420 may be in contact with each other.

The gate capping pattern 380 may be disposed on an upper surface of the third gate electrode 320 and an upper surface of the fourth gate electrode 420. The gate capping pattern 380 may cover the upper surface of the third gate electrode 320 and the upper surface of the fourth gate electrode 420. The gate capping pattern 380 may be in contact with a gate spacer 340. For example, a side surface of the gate capping pattern 380 may be in contact with the gate spacer 340. However, the present disclosure is not limited thereto. For example, the side surface of the gate capping pattern 380 may be in contact with a second etching stop film 355, and a lower surface of the gate capping pattern 380 may be in contact with the gate spacer 340.

For example, the gate capping pattern 380 may include at least one of silicon nitride (SiN), silicon oxynitride (SiON), silicon carbon nitride (SiCN), silicon oxycarbonitride (SiOCN), or a combination thereof. The gate capping pattern 380 may include a material having etch selectivity with respect to a second interlayer insulating film 390.

The gate spacer 340 may be disposed on a side surface of the third gate electrode 320 and the side surface of the gate capping pattern 380. For example, the gate spacer 340 may extend along the side surface of the third gate electrode 320, which is disposed above the plurality of third sheet patterns NS3.

For example, the gate spacer 340 may include at least one of silicon nitride (SiN), silicon nitride oxide (SiON), silicon dioxide (SiO₂), silicon carbonate (SiOCN), silicon boron nitride (SiBN), silicon oxyboron nitride (SiOBN), silicon oxycarbide (SiOC), or a combination thereof. Although the gate spacer 340 is illustrated as a single film, the present disclosure is not limited thereto.

The blocking spacer 160 may be disposed between the first gate electrode 120 and the second gate electrode 220 and between the third gate electrode 320 and the fourth gate electrode 420. In some implementations, the blocking spacer 160 may be disposed on at least one side of the gate isolation insulating film 170. In some implementations, the blocking spacer 160 may be disposed on both sides of the gate isolation insulating film 170. The blocking spacer 160 may extend along the gate isolation insulating film 170 in the second and third directions D2 and D3.

The blocking spacer 160 may include the first blocking spacer 162 and the second blocking spacer 164.

The first blocking spacer 162 may be disposed on the side surface BP1_SS of the first lower pattern BP1, the side surface NS1_SS of the first sheet pattern NS1, and the side surface NS3_SS of the third sheet pattern NS3. One side surface of the first blocking spacer 162 may be in contact with the side surface BP1_SS of the first lower pattern BP1, the side surface NS1_SS of the first sheet pattern NS1, and the side surface NS3_SS of the third sheet pattern NS3. The other side surface of the first blocking spacer 162 may be in contact with the gate isolation insulating film 170. In some implementations, the first blocking spacer 162 may have a uniform width in the first direction D1.

In some implementations, the first gate electrode 120 and the third gate electrode 320 may be disposed on one side surface of the first blocking spacer 162. For example, the first gate electrode 120 and the third gate electrode 320 may be in contact with the first blocking spacer 162. However, the present disclosure is not limited thereto. For example, another film may be disposed between the first gate electrode 120 and the first blocking spacer 162 and between the third gate electrode 320 and the first blocking spacer 162.

A lower portion of the first blocking spacer 162 may be disposed in the first device isolation trench ST1. A bottom surface of the first blocking spacer 162 may be disposed on the upper surface 100_US of the substrate 100. For example, the bottom surface of the first blocking spacer 162 may be in contact with the upper surface 100_US of the substrate 100.

In some implementations, as illustrated in FIG. 4, the upper surface 162_US of the first blocking spacer 162 may be disposed at the same level as an upper surface NS3_US of the third sheet pattern NS3. For example, a distance H1 from an upper surface 380_US of the gate capping pattern 380 to the upper surface NS3_US of the third sheet pattern NS3 may be equal to a distance H2 from the upper surface 380_US of the gate capping pattern 380 to the upper surface 162_US of the first blocking spacer 162. The upper surface NS3_US of the third sheet pattern NS3 may refer to the upper surface NS3_US of the third sheet pattern NS3 disposed uppermost among the plurality of third sheet patterns NS3.

In some implementations, as illustrated in FIG. 5, the upper surface 162_US of the first blocking spacer 162 may be disposed at a vertical level different from the upper surface NS3_US of the third sheet pattern NS3. For example, the distance H1 from the upper surface 380_US of the gate capping pattern 380 to the upper surface NS3_US of the third sheet pattern NS3 may be greater than the distance H2 from the upper surface 380_US of the gate capping pattern 380 to the upper surface 162_US of the first blocking spacer 162. Although the upper surface 162_US of the first blocking spacer 162 is illustrated as disposed on the same plane as the upper surface of a third gate insulating film 330, the present disclosure is not limited thereto. For example, the upper surface 162_US of the first blocking spacer 162 may be disposed at a higher vertical level than the upper surface of the third gate insulating film 330.

In some implementations, the upper surface 162_US of the first blocking spacer 162 may be disposed at a lower vertical level than the upper surface of the third gate electrode 320. For example, the distance from the upper surface 380_US of the gate capping pattern 380 to the upper surface of the third gate electrode 320 may be greater than the distance from the upper surface 380_US of the gate capping pattern 380 to the upper surface 162_US of the first blocking spacer 162.

The second blocking spacer 164 may be disposed on the side surfaces BP2_SS of the second lower pattern BP2, the side surfaces NS2_SS of the second sheet pattern NS2, and the side surfaces NS4_SS of the fourth sheet pattern NS4. One side surface of the second blocking spacer 164 may be in contact with the side surface BP2_SS of the second lower pattern BP2, the side surface NS2_SS of the second sheet pattern NS4, and the side surface NS4_SS of the fourth sheet pattern NS4. The other side surface of the second blocking spacer 164 may be in contact with the gate isolation insulating film 170. In some implementations, the second blocking spacer 164 may have a uniform width in the first direction D1.

In some implementations, the second gate electrode 220 and the fourth gate electrode 420 may be disposed on one side surface of the second blocking spacer 164. For example, the second gate electrode 220 and the fourth gate electrode 420 may be in contact with the second blocking spacer 164. However, the present disclosure is not limited thereto. For example, another film may be disposed between the second gate electrode 220 and the second blocking spacer 164 and between the fourth gate electrode 420 and the second blocking spacer 164.

A lower portion of the second blocking spacer 164 may be disposed in the first device isolation trench ST1. A bottom surface of the second blocking spacer 164 may be disposed on the upper surface 100_US of the substrate 100. For example, the bottom surface of the second blocking spacer 164 may be in contact with the upper surface 100_US of the substrate 100.

The description of the upper surface of the second blocking spacer 164 may be similar to the description of the upper surface 162_US of the first blocking spacer 162.

The gate isolation insulating film 170 may be disposed between the first blocking spacer 162 and the second blocking spacer 164. The first blocking spacer 162 and the second blocking spacer 164 may be disposed to be spaced apart from each other in the first direction D1 by the gate isolation insulating film 170. In other words, the first blocking spacer 162 and the second blocking spacer 164 may be separated from each other by the gate isolation insulating film 170.

For example, the blocking spacer 160 may include at least one of silicon nitride (SiN), silicon nitride oxide (SiON), silicon oxide (SiO2), silicon carbonate (SiOCN), silicon boron nitride (SiBN), silicon oxyboron nitride (SiOBN), silicon oxycarbide (SiOC), or a combination thereof.

The gate isolation insulating film 170 may be disposed on the substrate 100 and extend in the second and third directions D2 and D3. The gate isolation insulating film 170 may be disposed between the first gate electrode 120 and the second gate electrode 220 and between the third gate electrode 320 and the fourth gate electrode 420. The gate isolation insulating film 170 may separate the first gate electrode 120 and the second gate electrode 220 from each other and may separate the third gate electrode 320 and the fourth gate electrode 420 from each other.

A lower portion of the gate isolation insulating film 170 may be disposed in the first device isolation trench ST1. The gate isolation insulating film 170 and the blocking spacer 160 may fill the first device isolation trench ST1. A bottom surface of the gate isolation insulating film 170 may be disposed on the upper surface 100_US of the substrate 100. For example, the bottom surface of the gate isolation insulating film 170 may be in contact with the upper surface 100_US of the substrate 100.

The gate isolation insulating film 170 may include a stepped portion. The stepped portion of the gate isolation insulating film 170 may be disposed on the upper surface 162_US of the first blocking spacer 162. That is, the gate isolation insulating film 170 may be in contact with the first blocking spacer 162 on the upper surface 162_US and the side surface connected to the upper surface 162_US, respectively.

An upper portion 170_UP of the gate isolation insulating film 170 may overlap the blocking spacer 160 in the third direction D3. The upper portion 170_UP of the gate isolation insulating film 170 may refer to a partial region of the gate isolation insulating film 170 disposed at a higher level than the blocking spacer 160. The upper portion 170_UP of the gate isolation insulating film 170 may have a tapered shape. That is, the width of the upper portion 170_UP of the gate isolation insulating film 170 in the first direction D1 may decrease toward the blocking spacer 160. The upper portion 170_UP of the gate isolation insulating film 170 may extend through the gate capping pattern 380. The upper portion 170_UP of the gate isolation insulating film 170 may be in contact with the third gate electrode 320 and the fourth gate electrode 420.

The gate isolation insulating film 170 may include an insulating material. For example, the gate isolation insulating film 170 may include at least one of silicon nitride (SiN), silicon nitride oxide (SiON), silicon oxide (SiO2), silicon carbonate (SiOCN), silicon boron nitride (SiBN), silicon oxyboron nitride (SiOBN), silicon oxycarbide (SiOC), or a combination thereof.

A first source/drain pattern 150 may be disposed on the first active pattern AP1. The plurality of first sheet patterns NS1 may be disposed on a side surface of the first source/drain pattern 150. For example, the first source/drain pattern 150 may be disposed on at least one side of the plurality of first sheet patterns NS1. A lower surface of the first source/drain pattern 150 may be disposed on the field insulating film 105. Although the lower surface of the first source/drain pattern 150 is illustrated as disposed on the same plane as the bottom surface of the first gate insulating film 130, the present disclosure is not limited thereto. For example, the lower surface of the first source/drain pattern 150 may be disposed at a lower or higher level than the bottom surface of the first gate insulating film 130.

In some implementations, the second source/drain pattern may be disposed on the second active pattern AP2. For example, the plurality of second sheet patterns NS2 may be disposed on a side surface of the second source/drain pattern. The description with respect to the second source/drain pattern may be similar to the description with respect to the first source/drain pattern 150.

A third source/drain pattern 350 may be disposed on the third active pattern AP3. The plurality of third sheet patterns NS3 may be disposed on a side surface of the third source/drain pattern 350. For example, the third source/drain pattern 350 may be disposed on at least one side of the plurality of third sheet patterns NS3.

In some implementations, the fourth source/drain pattern may be disposed on the fourth active pattern AP4. For example, the plurality of fourth sheet patterns NS4 may be disposed on a side surface of the fourth source/drain pattern. The description with respect to the source/drain pattern may be similar to the description with respect to the third source/drain pattern 350.

Since the descriptions of the first to fourth source/drain patterns 150 and 350 may overlap, the first source/drain pattern 150 will be mainly described below.

The first source/drain pattern 150 may be an epitaxial pattern formed by a selective epitaxial growth process using the first active pattern AP1 as a seed. The first source/drain pattern 150 may serve as a source/drain of a transistor that uses the first sheet pattern NS1 as a channel region.

The first source/drain pattern 150 may include a semiconductor material. For example, the first source/drain pattern 150 may include an element semiconductor material such as silicon (Si) or germanium (Ge). In addition, for example, the first source/drain pattern 150 may include a binary compound or a ternary compound including at least two or more of carbon (C), silicon (Si), germanium (Ge), tin (Sn), or a compound of these doped with a group IV element. For example, the first source/drain pattern 150 may include silicon (Si), silicon-germanium (SiGe), germanium (Ge), silicon carbide (SiC), etc., but is not limited thereto.

The first source/drain pattern 150 may include impurities doped into a semiconductor material. The doped impurities may include at least one of boron (B), phosphorus (P), carbon (C), arsenic (As), antimony (Sb), bismuth (Bi), and oxygen (O), but the present disclosure is not limited thereto.

Although the first source/drain pattern 150 is illustrated as a single film, the present disclosure is not limited thereto. The first source/drain pattern 150 may include a plurality of films including different materials. In another aspect, the first source/drain pattern 150 may include the same material and may include a plurality of layers having different concentrations of constituent materials.

The first source/drain pattern 150 and the second source/drain pattern may have the same conductivity type. The third source/drain pattern 350 and the fourth source/drain pattern may have the same conductivity type. In some implementations, the first source/drain pattern 150 and the third source/drain pattern 350 may have different conductivity types. For example, the first source/drain pattern 150 may have a P-type conductivity, and the third source/drain pattern 350 may have an N-type conductivity. As another example, the first source/drain pattern 150 may have an N-type conductivity, and the third source/drain pattern 350 may have a P-type conductivity.

A first etching stop film 155 may be disposed on the first source/drain pattern 150. The first etching stop film 155 may cover an upper surface of the first source/drain pattern 150.

A first interlayer insulating film 190 may be disposed on the first etching stop film 155. The first interlayer insulating film 190 may be disposed between the first source/drain pattern 150 and the third source/drain pattern 350. The first source/drain pattern 150 and the third source/drain pattern 350 may be spaced apart from each other in the third direction D3 by the first interlayer insulating film 190.

The second etching stop film 355 may be disposed on an upper surface of the third source/drain pattern 350 and a side surface of the gate spacer 340. The second etching stop film 355 may cover the upper surface of the third source/drain pattern 350.

For example, each of the first etching stop film 155 and the second etching stop film 355 may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), or a combination thereof. The second etching stop film 355 may include a material having etching selectivity with respect to the second interlayer insulating film 390.

The second interlayer insulating film 390 may be disposed on the second etching stop film 355. For example, each of the first interlayer insulating film 190 and the second interlayer insulating film 390 may include at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

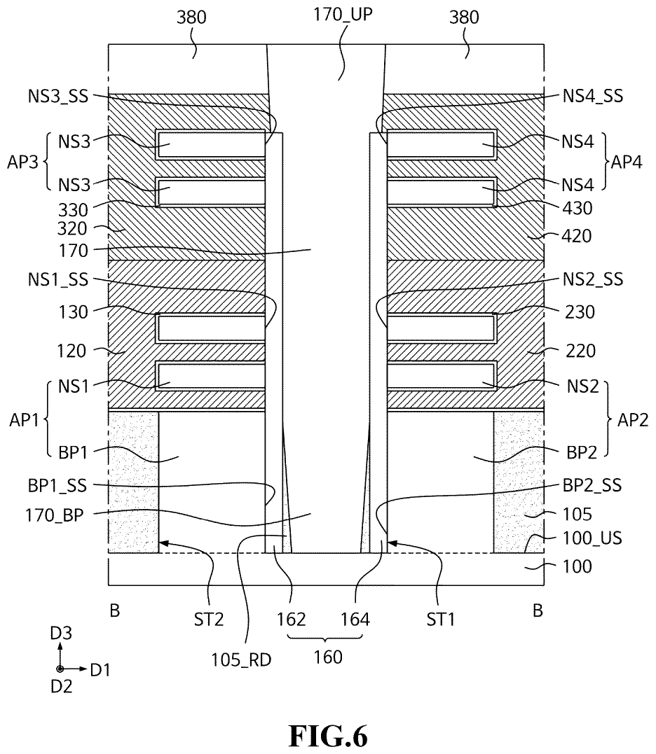

FIG. 6 is a diagram of an example of a semiconductor device. For convenience of description, different configurations from those described in FIGS. 1 to 5 will be mainly described.

Referring to FIG. 6, the semiconductor device further includes an insulating residue 105_RD.

The insulating residue 105_RD may be disposed on the first device isolation trench ST1. The insulating residue 105_RD may be disposed on a side surface of the blocking spacer 160. For example, the insulating residue 105_RD may be disposed between the first blocking spacer 162 and the gate isolation insulating film 170 and between the second blocking spacer 164 and the gate isolation insulating film 170.

In some implementations, the insulating residue 105_RD may include the same material as the field insulating film 105. The insulating residue 105_RD may refer to a portion that remains after the insulating material disposed in the first device isolation trench ST1 is removed in the process of forming the gate isolation insulating film 170. However, the present disclosure is not limited thereto. For example, the insulating residue 105_RD may include a material different from that of the field insulating film 105.

In some implementations, a lower portion 170_BP of the gate isolation insulating film 170 may have a tapered shape. The width of the lower portion 170_BP of the gate isolation insulating film 170 in the first direction D1 may decrease toward the substrate 100.

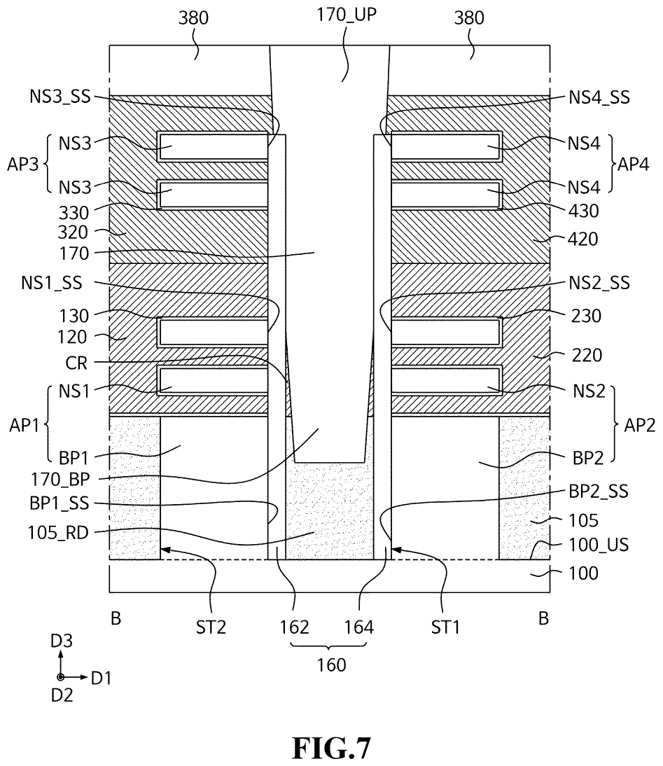

FIG. 7 is a diagram of an example of a semiconductor device. For convenience of description, different configurations from those described in FIGS. 1 to 6 will be mainly described.

Referring to FIG. 7, the semiconductor device further includes the insulating residue 105_RD and a conductive residue CR.

The gate isolation insulating film 170 may be disposed between the first blocking spacer 162 and the second blocking spacer 164. The gate isolation insulating film 170 may be disposed on the insulating residue 105_RD. For example, the bottom surface of the gate isolation insulating film 170 may be in contact with the insulating residue 105_RD. That is, the gate isolation insulating film 170 may be disposed to be spaced apart from the substrate 100 in the third direction D3 by the insulating residue 105_RD.

In some implementations, the lower portion 170_BP of the gate isolation insulating film 170 may have a tapered shape. The width of the lower portion 170_BP of the gate isolation insulating film 170 in the first direction D1 may decrease toward the substrate 100. The bottom surface of the gate isolation insulating film 170 may be disposed at a lower level than the bottom surface of the first gate electrode 120.

The conductive residue CR may be disposed on the side surface of the blocking spacer 160. For example, the conductive residue CR may be disposed between the first blocking spacer 162 and the lower portion 170_BP of the gate isolation insulating film 170 and between the second blocking spacer 164 and the lower portion 170_BP of the gate isolation insulating film 170.

In some implementations, the conductive residue CR may include the same material as those of the first and second gate electrodes 120 and 220. The conductive residue CR may be a portion that remains after the conductive material disposed between the first blocking spacer 162 and the second blocking spacer 164 is removed in the process of forming the gate isolation insulating film 170.

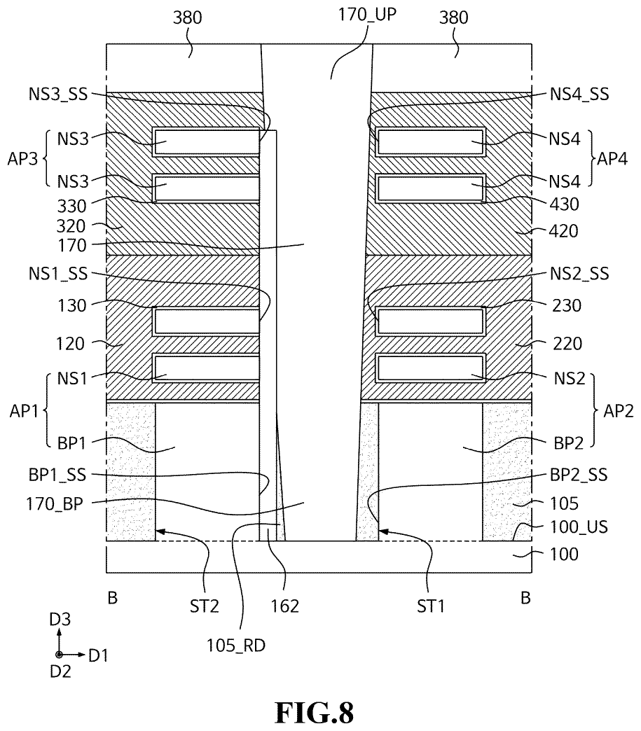

FIG. 8 is a diagram of an example of a semiconductor device. For convenience of description, different configurations from those described in FIGS. 1 to 5 will be mainly described.

Referring to the semiconductor device in FIG. 8, the first blocking spacer 162 is disposed on the gate isolation insulating film 170.

The first blocking spacer 162 may be disposed on one side surface of the gate isolation insulating film 170, and the second gate electrode 220 and the fourth gate electrode 420 may be disposed on the other side surface of the gate isolation insulating film 170. The other side surface of the gate isolation insulating film 170 may be in contact with the second gate electrode 220 and the fourth gate electrode 420.

The second gate electrode 220 may surround the second sheet pattern NS2. For example, the second gate electrode 220 may surround four surfaces of the second sheet pattern NS2. The second gate electrode 220 may be disposed between the side surface NS2_SS of the second sheet pattern NS2 and the gate isolation insulating film 170.

The fourth gate electrode 420 may surround the fourth sheet pattern NS4. For example, the fourth gate electrode 420 may surround four surfaces of the fourth sheet pattern NS4. The fourth gate electrode 420 may be disposed between the side surface NS4_SS of the fourth sheet pattern NS4 and the gate isolation insulating film 170.

The insulating residue 105_RD may be disposed in the first device isolation trench ST1. The insulating residue 105_RD may be disposed between the second lower pattern BP2 and the gate isolation insulating film 170 and between the gate isolation insulating film 170 and the first blocking spacer 162.

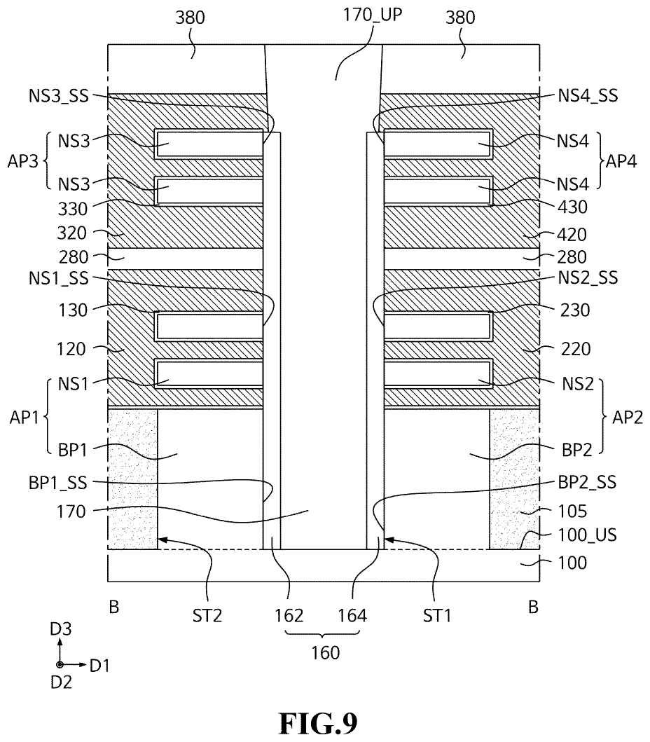

FIG. 9 is a diagram of an example of a semiconductor device. For convenience of description, different configurations from those described in FIGS. 1 to 5 will be mainly described.

Referring to FIG. 9, the semiconductor device further includes an interlayer gate isolation film 280.

The interlayer gate isolation film 280 may be disposed between the first gate electrode 120 and the third gate electrode 320 and between the second gate electrode 220 and the fourth gate electrode 420. The interlayer gate isolation film 280 may extend along the upper surface of the first gate electrode 120 and the upper surface of the second gate electrode 220. The first gate electrode 120 may not be in contact with the third gate electrode 320 and the second gate electrode 220 may not be in contact with the fourth gate electrode 420 due to the interlayer gate isolation film 280. For example, the first gate electrode 120 and the third gate electrode 320 may be spaced apart from each other in the third direction D3 by the interlayer gate isolation film 280. The second gate electrode 220 and the fourth gate electrode 420 may be spaced apart from each other in the third direction D3 by the interlayer gate isolation film 280. The interlayer gate isolation film 280 may include an insulating material.

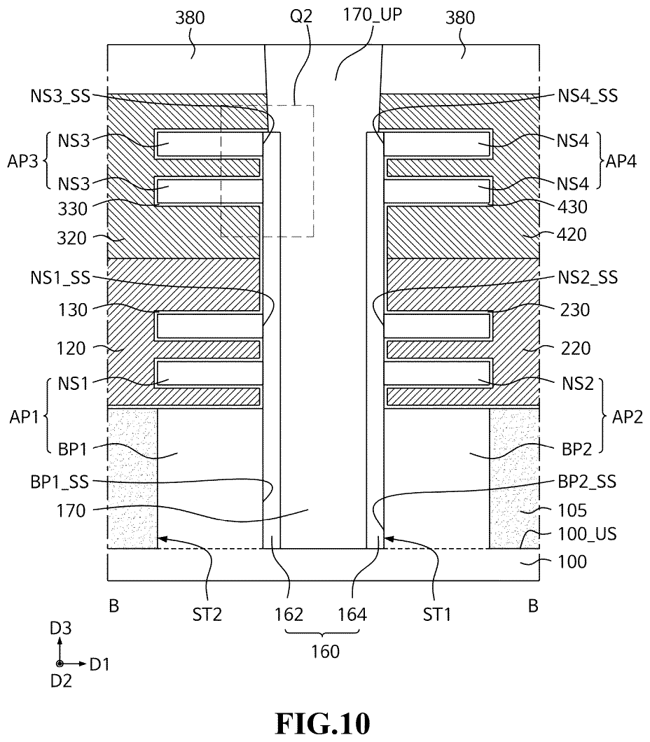

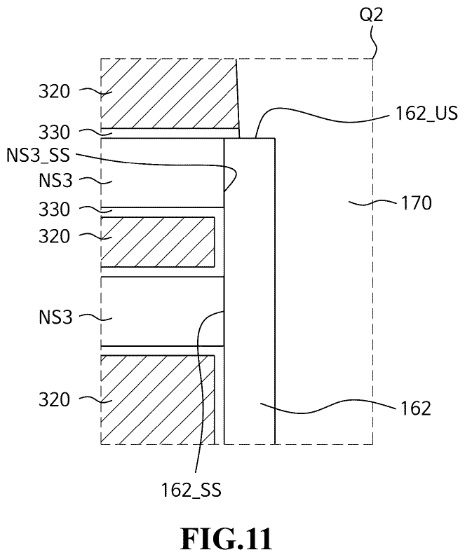

FIGS. 10 and 11 are diagrams of an example of a semiconductor device. For reference, FIG. 11 is an enlarged view of an example of the region Q2 of FIG. 10. For convenience of description, different configurations from those described in FIGS. 1 to 5 will be mainly described.

In the semiconductor device of FIGS. 10 and 11, the first to fourth gate insulating films 130, 230, 330, and 430 are disposed on the side surface of the blocking spacer 160.

The description of the first gate insulating film 130 may be similar to the description of the second gate insulating film 230, and the description of the third gate insulating film 330 may be similar to the description of a fourth gate insulating film 430. Hereinafter, the first gate insulating film 130 and the third gate insulating film 330 will be mainly described.

The first gate insulating film 130 may surround the first sheet pattern NS1. The first gate insulating film 130 may be disposed between the first gate electrode 120 and the first blocking spacer 162. The first gate insulating film 130 may be disposed on a side surface 162_SS of the first blocking spacer 162. The first gate insulating film 130 may extend along the side surface 162_SS of the first blocking spacer 162.

The third gate insulating film 330 may surround the third sheet pattern NS3. The third gate insulating film 330 may be disposed between the third gate electrode 320 and the first blocking spacer 162. The third gate insulating film 330 may be disposed on the side surface 162_SS of the first blocking spacer 162. The third gate insulating film 330 may extend along the side surface 162_SS of the first blocking spacer 162. A portion of the third gate insulating film 330 may be disposed on the upper surface 162_US of the first blocking spacer 162.

The first gate insulating film 130 and the third gate insulating film 330 may be connected to each other on the side surface 162_SS of the first blocking spacer 162. In some implementations, the first gate insulating film 130 and the third gate insulating film 330 may be formed by the same manufacturing process.

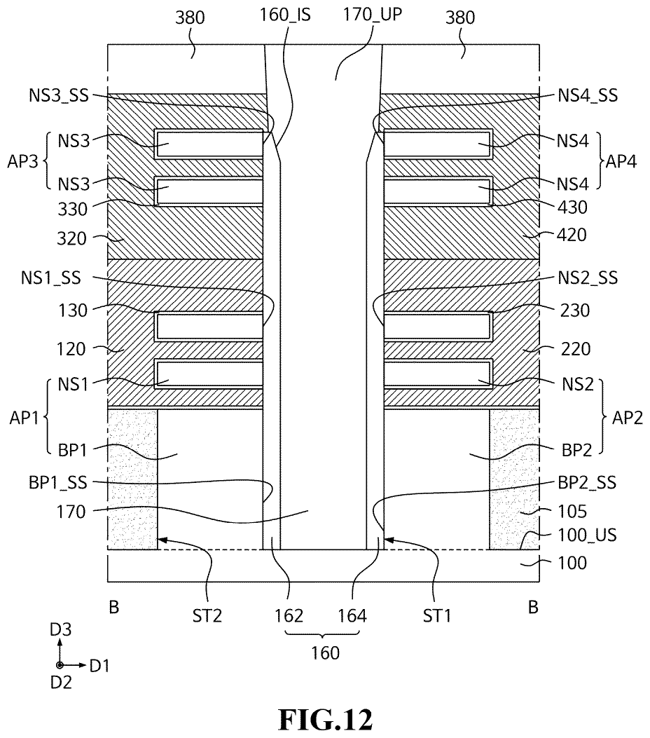

FIG. 12 is a diagram of an example of a semiconductor device. For convenience of description, different configurations from those described in FIGS. 1 to 5 will be mainly described.

Referring to FIG. 12, in the semiconductor device, the blocking spacer 160 includes an inclined surface 160_IS.

The inclined surface 160_IS of the blocking spacer 160 may be disposed on an upper portion of the blocking spacer 160. The inclined surface 160_IS of the blocking spacer 160 may be connected to the upper surface and the side surface of the blocking spacer 160. The side surface of the blocking spacer 160 may be a surface in contact with the gate isolation insulating film 170. The inclined surface 160_IS of the blocking spacer 160 may form an acute angle with the upper surface 100_US of the substrate 100.

The gate isolation insulating film 170 may be disposed between the first blocking spacer 162 and the second blocking spacer 164. The gate isolation insulating film 170 may be disposed on the inclined surface 160_IS of the blocking spacer 160.

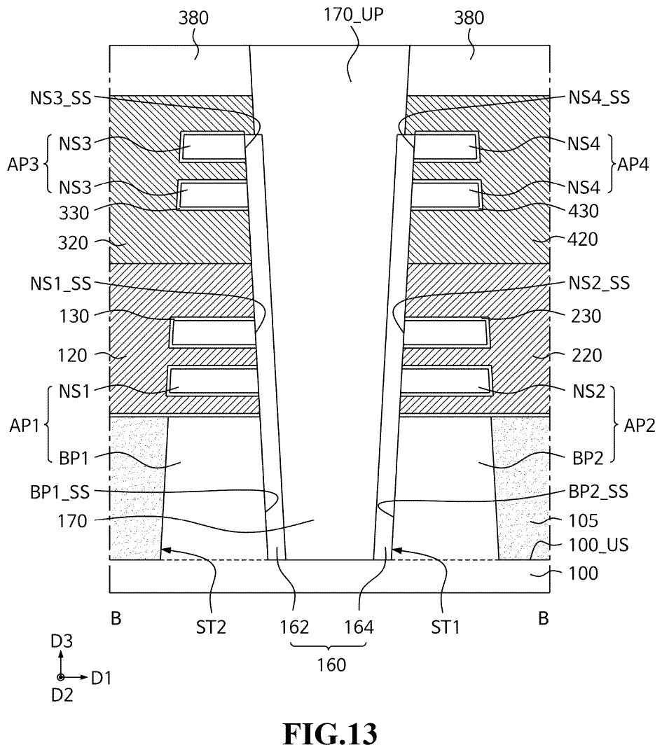

FIG. 13 is a diagram of an example of a semiconductor device. For convenience of description, different configurations from those described in FIGS. 1 to 5 will be mainly described.

In the semiconductor device of FIG. 13, widths of the first and second lower patterns BP1 and BP2 and the first to fourth sheet patterns NS1, NS2, NS3, and NS4 are not constant in the first direction D1.

The width of the first lower pattern BP1 in the first direction D1 may decrease as the distance from the substrate 100 increases. The side surface BP1_SS of the first lower pattern BP1 may be inclined with respect to the upper surface 100_US of the substrate 100.

The width of the first sheet pattern NS1 in the first direction D1 may be less than the width of the first lower pattern BP1 in the first direction D1. The width of the first sheet pattern NS1 in the first direction D1 may decrease as the distance from the substrate 100 increases. The side surface NS1_SS of the first sheet pattern NS1 may be inclined with respect to the upper surface 100_US of the substrate 100.

The width of the third sheet pattern NS3 in the first direction D1 may be less than the width of the first sheet pattern NS1 in the first direction D1. The width of the third sheet pattern NS3 in the first direction D1 may decrease as the distance from the substrate 100 increases. The side surface NS3_SS of the third sheet pattern NS3 may be inclined with respect to the upper surface 100_US of the substrate 100.

The first blocking spacer 162 may extend along the side surface BP1_SS of the first lower pattern BP1, the side surface NS1_SS of the first sheet pattern NS1, and the third sheet pattern NS3_SS. The first blocking spacer 162 may be inclined with respect to the upper surface 100_US of the substrate 100.

The width of the second lower pattern BP2 in the first direction D1 may decrease as the distance from the substrate 100 increases. The side surface BP2_SS of the second lower pattern BP2 may be inclined with respect to the upper surface 100_US of the substrate 100.

The width of the second sheet pattern NS2 in the first direction D1 may be greater than the width of the second lower pattern BP2 in the first direction D1. The width of the second sheet pattern NS2 in the first direction D1 may decrease as the distance from the substrate 100 increases. The side surface NS2_SS of the second sheet pattern NS2 may be inclined with respect to the upper surface 100_US of the substrate 100.

The width of the fourth sheet pattern NS4 in the first direction D1 may be less than the width of the second sheet pattern NS2 in the first direction D1. The width of the fourth sheet pattern NS4 in the first direction D1 may decrease as the distance from the substrate 100 increases. The side surface NS4_SS of the fourth sheet pattern NS4 may be inclined with respect to the upper surface 100_US of the substrate 100.

The second blocking spacer 164 may extend along the side surface BP2_SS of the second lower pattern BP2, the side surface NS2_SS of the second sheet pattern NS2, and the fourth sheet pattern NS4_SS. The second blocking spacer 164 may be inclined with respect to the upper surface 100_US of the substrate 100.

The gate isolation insulating film 170 may be disposed between the first blocking spacer 162 and the second blocking spacer 164. The width of the gate isolation insulating film 170 in the first direction D1 may decrease toward the substrate 100. The gate isolation insulating film 170 may have a tapered shape.

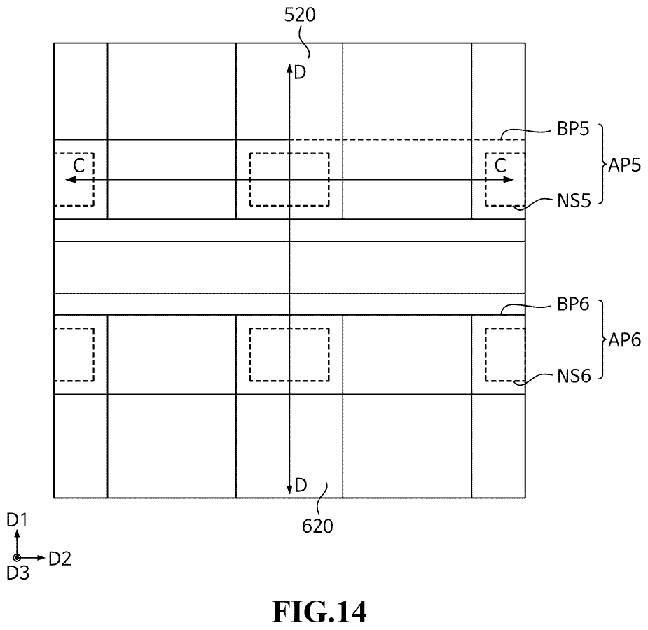

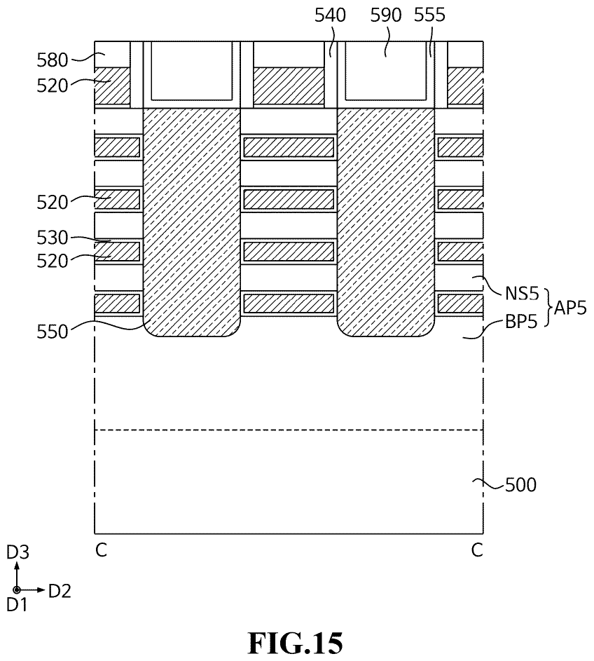

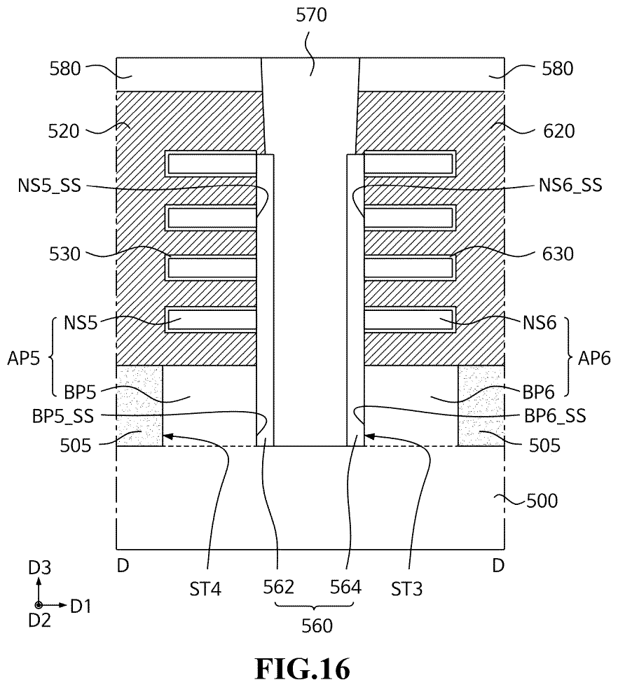

FIG. 14 is a plan view of an example of a semiconductor device. FIG. 15 is a cross-sectional view taken along line C-C of FIG. 14. FIG. 16 is a cross-sectional view taken along line D-D of FIG. 14. For convenience of description, configurations overlapping the configurations already described above with reference to FIGS. 1 to 5 will be omitted or briefly described.

Referring to FIGS. 14 to 16, the semiconductor device includes a substrate 500, a fifth active pattern AP5, a sixth active pattern AP6, a fifth gate electrode 520, a sixth gate electrode 620, a blocking spacer 560, a gate isolation insulating film 570, a gate capping pattern 580, etc.

The substrate 500 may be a bulk silicon or a silicon-on-insulator (SOI). In some implementations, the substrate 500 may include silicon germanium (SiGe), silicon germanium on insulator (SGOI), indium antimony, lead tellurium compound, indium arsenic, indium phosphide, gallium arsenic, or gallium antimony, but is not limited thereto.

The fifth active pattern AP5 may be disposed on the substrate 500. The fifth active pattern AP5 may extend in the second direction D2. The sixth active pattern AP6 may be disposed on the substrate 500. The sixth active pattern AP6 may extend in the second direction D2. The sixth active pattern AP6 may be disposed to be spaced apart from the fifth active pattern AP5 in the first direction D1. Each of the first and second directions D1 and D2 may be a direction parallel to the upper surface of the substrate 500.

The fifth active pattern AP5 may include a fifth lower pattern BP5 and a plurality of fifth sheet patterns NS5. The sixth active pattern AP6 may include a sixth lower pattern BP6 and a plurality of sixth sheet patterns NS6.

Each of the fifth lower pattern BP5 and the sixth lower pattern BP6 may protrude from the substrate 500. Each of the fifth lower pattern BP5 and the sixth lower pattern BP6 may extend in the second direction D2. The fifth lower pattern BP5 may be disposed to be spaced apart from the sixth lower pattern BP6 in the first direction D1. The fifth lower pattern BP5 and the sixth lower pattern BP6 may be separated from each other by a third device isolation trench ST3. The third device isolation trench ST3 may be defined by an upper surface of the substrate 500, a side surface BP5_SS of the fifth lower pattern BP5, and a side surface BP6_SS of the sixth lower pattern BP6.

The plurality of fifth sheet patterns NS5 may be disposed on the fifth lower pattern BP5. The plurality of fifth sheet patterns NS5 may be spaced apart from the fifth lower pattern BP5 in the third direction D3. Each of the fifth sheet patterns NS5 may be spaced apart from each other in the third direction D3. The third direction D3 may be a direction intersecting each of the first and second directions D1 and D2. The third direction D3 may be a direction perpendicular to the upper surface of the substrate 500. The third direction D3 may be a thickness direction of the substrate 500. Although it is illustrated that there are four fifth sheet patterns NS5, the present disclosure is not limited thereto.

The plurality of sixth sheet patterns NS6 may be disposed on the sixth lower pattern BP6. The plurality of sixth sheet patterns NS6 may be spaced apart from the sixth lower pattern BP6 in the third direction D3. Each of the sixth sheet patterns NS6 may be spaced apart from each other in the third direction D3. Although it is illustrated that there are four sixth sheet patterns NS6, the present disclosure is not limited thereto.

The description of the materials of the fifth and sixth lower patterns BP5 and BP6 and the fifth and sixth sheet patterns NS5 and NS6 may be the same as the description of the first and second lower patterns BP1 and BP2 and the first and second sheet patterns NS1 and NS2 described in FIG. 3.

A field insulating film 505 may be disposed on a fourth device isolation trench ST4. The field insulating film 505 may fill the fourth device isolation trench ST4. The fourth device isolation trench ST4 may be disposed to be spaced apart from the third device isolation trench ST3 in the first direction D1. For example, the field insulating film 505 may include an oxide, a nitride, a nitride oxide, or a combination thereof. Although the field insulating film 505 is illustrated as a single film, the present disclosure is not limited thereto. For example, the field insulating film 505 may be formed of a plurality of films.

The fifth gate electrode 520 may be disposed on the field insulating film 105 and the fifth lower pattern BP5. The fifth gate electrode 520 may extend in the first direction D1. The fifth gate electrode 520 may intersect the fifth active pattern AP5. The fifth gate electrode 520 may be disposed between the plurality of fifth sheet patterns NS5. The fifth gate electrode 520 may be disposed between the fifth sheet pattern NS5 disposed lowermost among the plurality of fifth sheet patterns NS5, and the fifth lower pattern BP5. The fifth gate electrode 520 may surround the fifth sheet pattern NS5. For example, the fifth gate electrode 520 may surround three surfaces of the fifth sheet pattern NS5. The fifth gate electrode 520 may not be disposed between a side surface NS5_SS of the fifth sheet pattern NS5 and a third blocking spacer 562.

The sixth gate electrode 620 may be disposed on the field insulating film 505 and the sixth lower pattern BP6. The sixth gate electrode 620 may extend in the first direction D1. The sixth gate electrode 620 may intersect the sixth active pattern AP6. The sixth gate electrode 620 may be disposed between the plurality of sixth sheet patterns NS6. The sixth gate electrode 620 may be disposed between the sixth sheet pattern NS6 disposed lowermost among the plurality of sixth sheet patterns NS6, and the sixth lower pattern BP6. The sixth gate electrode 620 may surround the sixth sheet pattern NS6. For example, the sixth gate electrode 620 may surround three surfaces of the sixth sheet pattern NS6. The sixth gate electrode 620 may not be disposed between a side surface NS6_SS of the sixth sheet pattern NS6 and a fourth blocking spacer 564.

The fifth gate electrode 520 may overlap the sixth gate electrode 620 in the first direction D1. The fifth gate electrode 520 may be spaced apart from the sixth gate electrode 620 in the first direction D1. The blocking spacer 560 and the gate isolation insulating film 570 may be disposed between the fifth gate electrode 520 and the sixth gate electrode 620.

The description of the materials of the fifth gate electrode 520 and the sixth gate electrode 620 may be the same as the description of the first gate electrode 120 and the second gate electrode 220 described in FIG. 3. In some implementations, the fifth gate electrode 520 and the sixth gate electrode 620 may include the same material.

A fifth gate insulating film 530 may be disposed between the fifth gate electrode 520 and the fifth sheet pattern NS5 and between the fifth gate electrode 520 and the fifth lower pattern BP5. The fifth gate insulating film 530 may surround the fifth sheet pattern NS5. For example, the fifth gate insulating film 530 may surround three surfaces of the fifth sheet pattern NS5. The fifth gate insulating film 530 may not be disposed on the side surface NS5_SS of the fifth sheet pattern NS5. The third blocking spacer 562 may be disposed on the side surface NS5_SS of the fifth sheet pattern NS5.

A sixth gate insulating film 630 may be disposed between the sixth gate electrode 620 and the sixth sheet pattern NS6 and between the sixth gate electrode 620 and the sixth lower pattern BP6. The sixth gate insulating film 630 may surround the sixth sheet pattern NS6. For example, the sixth gate insulating film 630 may surround three surfaces of the sixth sheet pattern NS6. The sixth gate insulating film 630 may not be disposed on the side surface NS6_SS of the sixth sheet pattern NS6. The fourth blocking spacer 564 may be disposed on the side surface NS6_SS of the sixth sheet pattern NS6.

Although each of the fifth gate insulating film 530 and the sixth gate insulating film 630 is illustrated as a single film, each of the fifth gate insulating film 530 and the sixth gate insulating film 630 may include a plurality of films. For example, each of the fifth gate insulating film 530 and the sixth gate insulating film 630 may include an interface insulating film and a high-k insulating film.

In some implementations, the fifth gate insulating film 530 may be disposed on a side surface of the third blocking spacer 562, and the sixth gate insulating film 630 may be disposed on a side surface of the fourth blocking spacer 564. For example, the fifth gate insulating film 530 may be disposed between the fifth gate electrode 520 and the side surface of the third blocking spacer 562. The sixth gate insulating film 630 may be disposed between the sixth gate electrode 620 and the side surface of the fourth blocking spacer 564.

The gate capping pattern 580 may be disposed on an upper surface of the fifth gate electrode 520 and an upper surface of the sixth gate electrode 620. The gate capping pattern 580 may cover the upper surface of the fifth gate electrode 520 and the upper surface of the sixth gate electrode 620.

A gate spacer 540 may be disposed on a side surface of the fifth gate electrode 520 and a side surface of the gate capping pattern 580. For example, the gate spacer 540 may extend along the side surface of the fifth gate electrodes 520, which is disposed above the plurality of fifth sheet patterns NS5.

The blocking spacer 560 may be disposed between the fifth gate electrode 520 and the sixth gate electrode 620. In some implementations, the blocking spacer 560 may be disposed on both sides of the gate isolation insulating film 570. The blocking spacer 560 may extend along the gate isolation insulating film 570 in the second and third directions D2 and D3.

The blocking spacer 560 may include at least one of the third blocking spacer 562 and the fourth blocking spacer 564.

The third blocking spacer 562 may be disposed on the side surface BP5_SS of the fifth lower pattern BP5 and the side surface NS5_SS of the fifth sheet pattern NS5. One side surface of the third blocking spacer 562 may be in contact with the side surface BP5_SS of the fifth lower pattern BP5 and the side surface NS5_SS of the fifth sheet pattern NS5. The other side surface of the third blocking spacer 562 may be in contact with the gate isolation insulating film 570.

The fourth blocking spacer 564 may be disposed on the side surface BP6_SS of the sixth lower pattern BP6 and the side surface NS6_SS of the sixth sheet pattern NS6. One side surface of the fourth blocking spacer 564 may be in contact with the side surface BP6_SS of the sixth lower pattern BP6 and the side surface NS6_SS of the sixth sheet pattern NS6. The other side surface of the fourth blocking spacer 564 may be in contact with the gate isolation insulating film 570.

Lower portions of the third blocking spacer 562 and the fourth blocking spacer 564 may be disposed in the third device isolation trench ST3. Bottom surfaces of the third blocking spacer 562 and the fourth blocking spacer 564 may be disposed on the upper surface of the substrate 500. In some implementations, the bottom surfaces of the third blocking spacer 562 and the fourth blocking spacer 564 may be in contact with the upper surface of the substrate 500. However, the present disclosure is not limited thereto.

Although the upper surface of the third blocking spacer 562 and the upper surface of the fifth sheet pattern NS5 are illustrated as disposed at the same level, the present disclosure is not limited thereto. For example, the upper surface of the third blocking spacer 562 may be disposed at a higher level than the upper surface of the fifth sheet pattern NS5.

The gate isolation insulating film 570 may be disposed between the third blocking spacer 562 and the fourth blocking spacer 564. The third blocking spacer 562 and the fourth blocking spacer 564 may be disposed to be spaced apart from each other in the first direction D1 by the gate isolation insulating film 570. In other words, the third blocking spacer 562 and the fourth blocking spacer 564 may be separated from each other by the gate isolation insulating film 570.

The gate isolation insulating film 570 may be disposed on the substrate 500 and may extend in the second and third directions D2 and D3. The gate isolation insulating film 570 may be disposed between the fifth gate electrode 520 and the sixth gate electrode 620. The gate isolation insulating film 570 may separate the fifth gate electrode 520 from the sixth gate electrode 620.

A lower portion of the gate isolation insulating film 570 may be disposed in the third device isolation trench ST3. The gate isolation insulating film 570 and the blocking spacer 560 may fill the third device isolation trench ST3. A bottom surface of the gate isolation insulating film 570 may be disposed on the upper surface of the substrate 500.

The gate isolation insulating film 570 may include a stepped portion. The stepped portion of the gate isolation insulating film 570 may be disposed on the upper surface of the blocking spacer 560.

An upper portion of the gate isolation insulating film 570 may overlap the blocking spacer 560 in the third direction D3. The upper portion 570_UP of the gate isolation insulating film 570 may refer to the gate isolation insulating film 570 disposed at a higher level than the blocking spacer 560. The upper portion of the gate isolation insulating film 570 may have a tapered shape. That is, the width of the upper portion of the gate isolation insulating film 570 in the first direction D1 may decrease toward the blocking spacer 560. The upper portion of the gate isolation insulating film 570 may extend through the gate capping pattern 580.

The description of the material of the blocking spacer 560 and the gate isolation insulating film 570 may be the same as the description of the blocking spacer 160 and the gate isolation insulating film 170 described in FIG. 3.

A fifth source/drain pattern 550 may be disposed on the fifth active pattern AP5. The fifth source/drain pattern 550 may be disposed on the plurality of fifth sheet patterns NS5. For example, the fifth source/drain pattern 550 may be disposed on at least one side of the plurality of fifth sheet patterns NS5. The fifth source/drain pattern 550 may connect the fifth sheet patterns NS5 spaced apart from each other in the second direction D2.

The fifth source/drain pattern 550 may be disposed on at least one side of the fifth gate electrode 520. The fifth source/drain pattern 550 may be disposed between the fifth gate electrodes 520 adjacent to each other in the second direction D2. The description of the material of the fifth source/drain pattern 550 may be the same as the description of the first source/drain pattern 150 described with reference to FIG. 2.

A third etching stop film 555 may be disposed on an upper surface of the fifth source/drain pattern 550 and a side surface of the gate spacer 540. The third etching stop film 555 may cover the upper surface of the fifth source/drain pattern 550. The second interlayer insulating film 390 may be disposed on the third etching stop film 555.

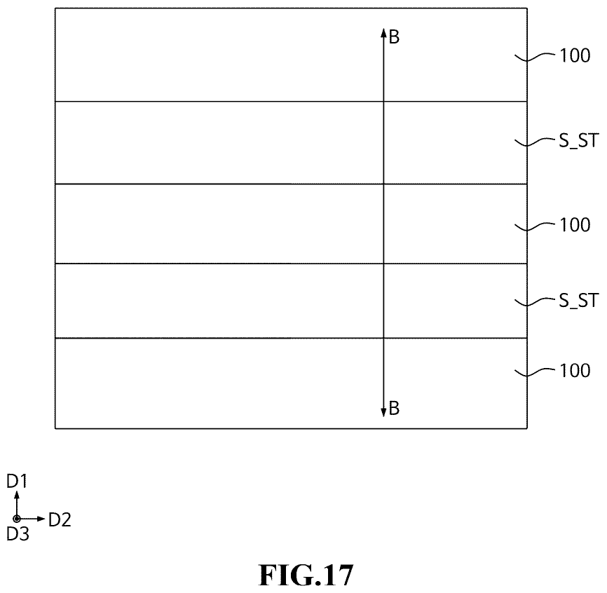

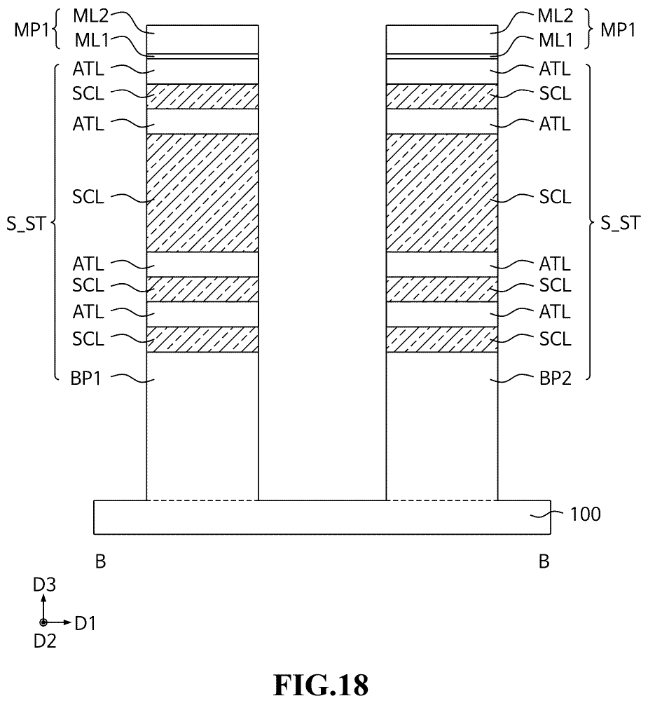

FIGS. 17 to 25 are diagrams illustrating intermediate stages, which are part of an example of a method for manufacturing a semiconductor device. For reference, FIG. 17 is a plan view of a semiconductor device, and FIGS. 18 to 25 are cross-sectional views taken along line B-B of FIG. 17.

Referring to FIGS. 17 and 18, the method for manufacturing the semiconductor device includes forming a stacked structure S_ST on the substrate 100.

The substrate 100 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony.

The stack structure S_ST may be formed on the substrate 100. The stacked structure S_ST may extend in the second direction D2. The stack structure S_ST may include the lower patterns BP1 and BP2, and a plurality of sacrificial semiconductor layers SCL and a plurality of active semiconductor layers ATL, which are alternately stacked on each other on the lower patterns BP1 and BP2.

In some implementations, the lower patterns BP1 and BP2 may be formed by etching a portion of the substrate 100. A boundary surface between the substrate 100 and the lower patterns BP1 and BP2 may not be distinguished.

A first mask pattern MP1 may be disposed on an upper surface of the stack structure S_ST. The upper surface of the stack structure S_ST may be an upper surface of the active semiconductor layer ATL disposed uppermost among the plurality of active semiconductor layers ATL. The first mask pattern MP1 may cover the upper surface of the stack structure S_ST.

In some implementations, the first mask pattern MP1 may include a first mask layer ML1 and a second mask layer ML2. The first mask layer ML1 may include silicon oxide, and the second mask layer ML2 may include silicon nitride.

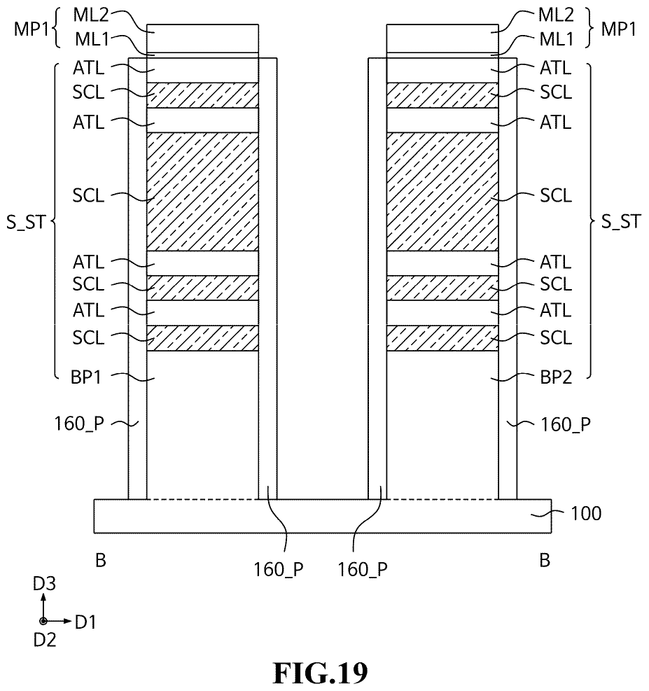

Referring to FIG. 19, a pre-blocking spacer 160_P is formed on a side surface of the stack structure S_ST.

The pre-blocking spacer 160_P may extend in the second and third directions D2 and D3. The pre-blocking spacers 160_P may be disposed on both side surfaces of the stack structure S_ST. In some implementations, the pre-blocking spacer 160_P may be in contact with the side surface of the active semiconductor layer ATL. The pre-blocking spacer 160_P may have the same thickness in the first direction D1.

In some implementations, an upper surface of the pre-blocking spacer 160_P may be disposed at the same level as the upper surface of the stack structure S_ST. However, the present disclosure is not limited thereto. The upper surface of the pre-blocking spacer 160_P may be disposed at a different level from the upper surface of the stack structure S_ST.

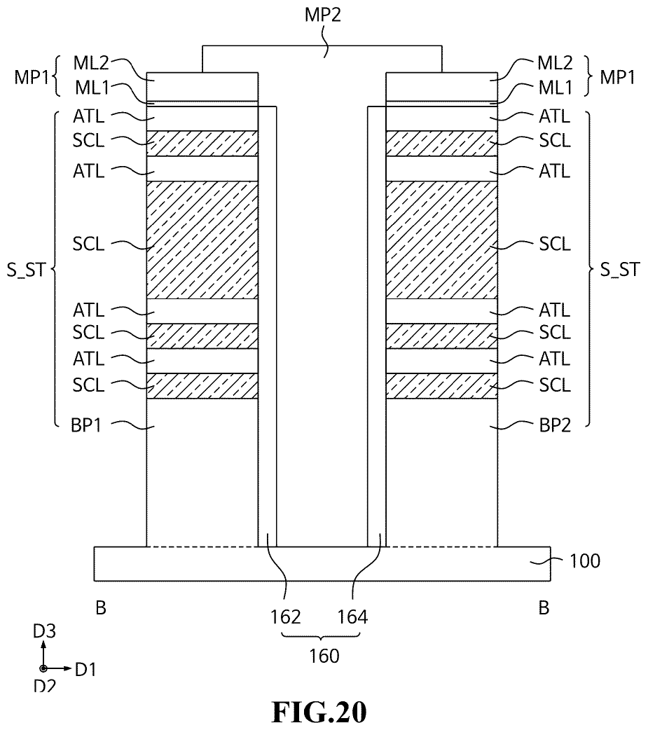

Referring to FIGS. 19 and 20, a portion of the pre-blocking spacer 160_P is removed to form the blocking spacer 160.

Specifically, a second mask pattern MP2 may be formed on the stack structure S_ST. The second mask pattern MP2 may cover a portion of the pre-blocking spacer 160_P and expose the remaining portion of the pre-blocking spacer 160_P. The exposed pre-blocking spacer 160_P may be removed, and the blocking spacer 160 may be formed. The blocking spacer 160 may cover the side surface of the stack structure S_ST.

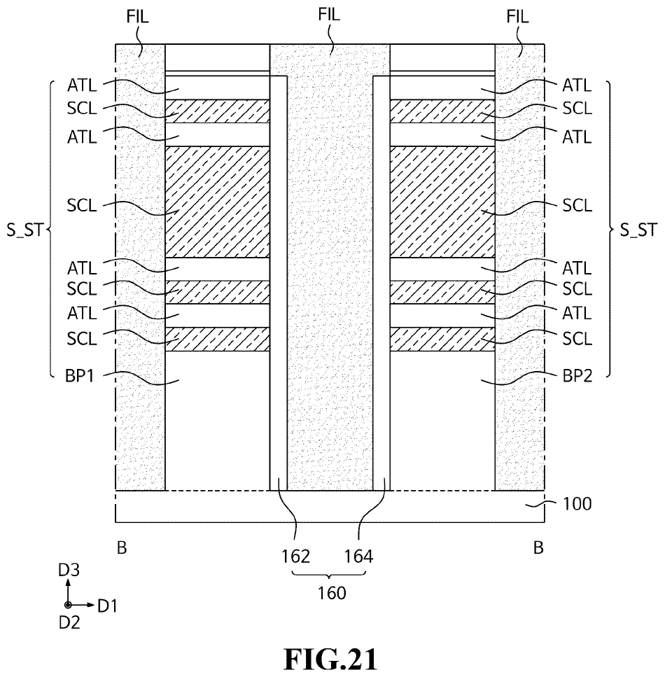

Referring to FIGS. 20 and 21, the second mask pattern MP2 is removed, and a filling insulating film FIL may be formed on the substrate 100.

The filling insulating film FIL may cover the upper surface 100_US of the substrate 100. The filling insulating film FIL may fill a space between the first blocking spacer 162 and the second blocking spacer 164. The filling insulating film FIL may be disposed on the side surface of the stack structure S_ST. For example, the filling insulating film FIL may be disposed on the side surface of the stack structure S_ST where the blocking spacer 160 is not disposed.

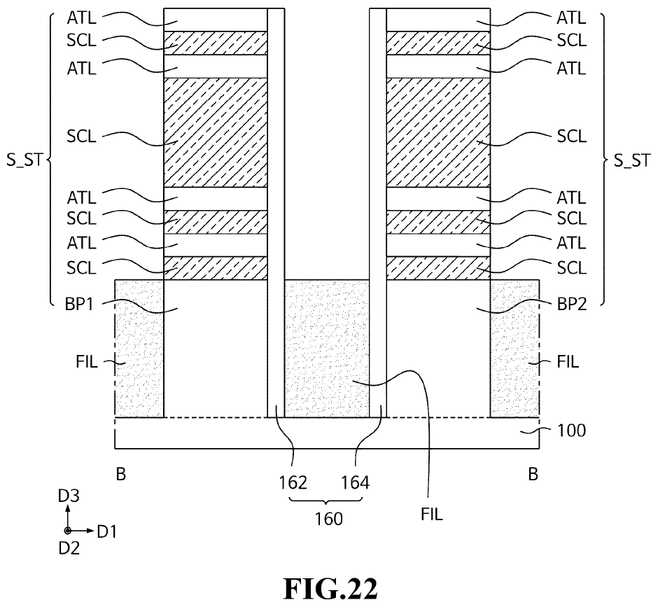

Referring to FIGS. 21 and 22, a portion of the filling insulating film FIL is removed such that the height of the filling insulating film FIL may be reduced. The height of the filling insulating film FIL may refer to a length in the third direction D3. The first mask pattern MP1 may be removed, and the upper surface of the stack structure S_ST may be exposed.

In some implementations, the upper surface of the filling insulating film FIL may be disposed at the same level as the upper surface of the lower patterns BP1 and BP2. However, the present disclosure is not limited thereto.

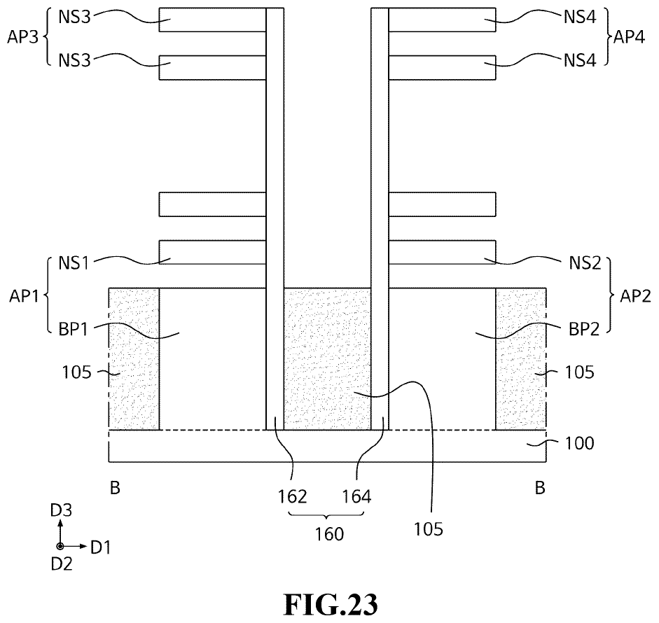

Referring to FIGS. 22 and 23, the sacrificial semiconductor layer SCL is removed, and the first to fourth active patterns AP1, AP2, AP3, and AP4 may be formed.

Specifically, a portion of the stack structure S_ST extending in the second direction D2 may be removed, and source/drain patterns (e.g., the first source/drain pattern 150 and the third source/drain pattern 350 of FIG. 2) may be formed. The sacrificial semiconductor layer SCL may be removed, and the first to fourth sheet patterns NS1, NS2, NS3, and NS4 may be formed. The side surface of each of the first to fourth sheet patterns NS1, NS2, NS3, and NS4 may be in contact with the blocking spacer 160.

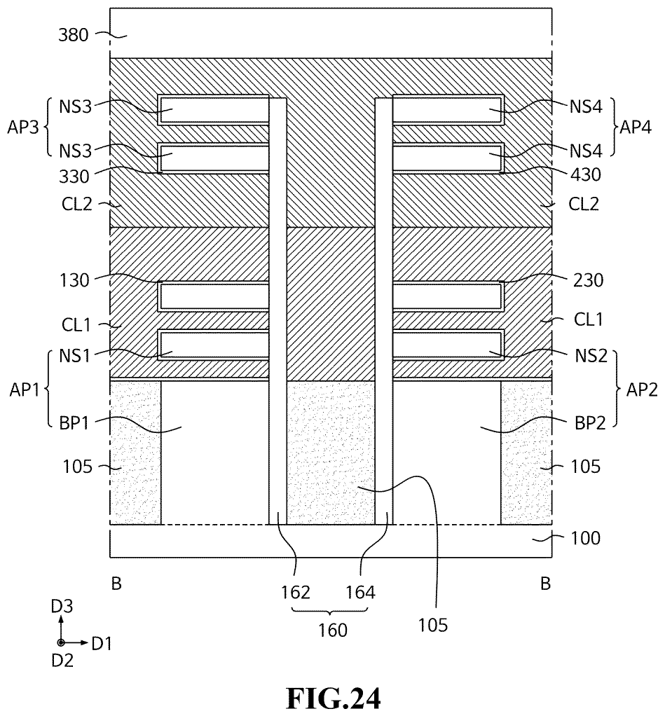

Referring to FIG. 24, the first to fourth gate insulating films 130, 230, 330, and 430 may be formed on the first to fourth sheet patterns NS1, NS2, NS3, and NS4, respectively, and a first conductive film CL1 and a second conductive film CL2 may be formed.

Specifically, the first gate insulating film 130 may be formed on the first sheet pattern NS1 and the first lower pattern BP1. The first gate insulating film 130 may not be disposed between the first sheet pattern NS1 and the first blocking spacer 162. The second gate insulating film 230 may be formed on the second sheet pattern NS2 and the second lower pattern BP2. The second gate insulating film 230 may not be disposed between the second sheet pattern NS2 and the second blocking spacer 164.

The third gate insulating film 330 may be formed on the third sheet pattern NS3. The third gate insulating film 330 may not be disposed between the third sheet pattern NS3 and the first blocking spacer 162. The fourth gate insulating film 430 may be formed on the fourth sheet pattern NS3. The fourth gate insulating film 430 may not be formed between the fourth sheet pattern NS4 and the second blocking spacer 164.

In some implementations, the first to fourth gate insulating films 130, 230, 330, and 430 may be formed at the same time. The first to fourth gate insulating films 130, 230, 330, and 430 may be formed by the same manufacturing process.

In some implementations, the first gate insulating film 130 and the third gate insulating film 330 may be connected to each other. The first gate insulating film 130 and the third gate insulating film 330 may surround the first blocking spacer 162. The shapes of the first gate insulating film 130 and the third gate insulating film 330 may be similar to those of FIG. 10.

The first conductive film CL1 may be formed on the first gate insulating film 130 and the second gate insulating film 230, and the second conductive film CL2 may be formed on the third gate insulating film 330 and the fourth gate insulating film 430. The second conductive film CL2 may be disposed on the first conductive film CL1. The gate capping pattern 380 may be formed on the second conductive film CL2. The gate capping pattern 380 may be disposed on an upper surface of the second conductive film CL2.

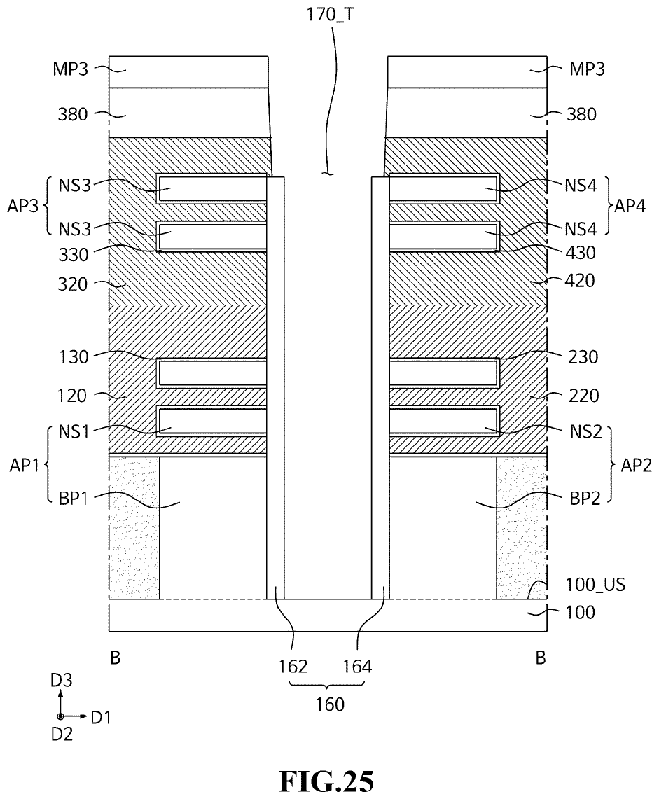

Referring to FIGS. 24 and 25, a gate isolation trench 170_T is formed between the first blocking spacer 162 and the second blocking spacer 164.

Specifically, a third mask pattern MP3 may be formed on the gate capping pattern 380. An etching process may be performed using the third mask pattern MP3 as an etching mask. The gate isolation trench 170_T may be formed in the etching process. The gate isolation trench 170_T may extend through the gate capping pattern 380, the first conductive film CL1, and the second conductive film CL2. The gate isolation trench 170_T may expose the upper surface 100_US of the substrate 100. The gate isolation trench 170_T may expose a portion of an upper surface of the blocking spacer 160.

The first conductive film CL1 may be separated by the etching process to form the first gate electrode 120 and the second gate electrode 220, and the second conductive film CL2 may be separated to form the third gate electrode 320 and the fourth gate electrode 420.

In some implementations, the etching process of forming the gate isolation trench 170_T may use the blocking spacer 160 as an etching mask. The etching process may remove the material disposed between the first blocking spacer 162 and the second blocking spacer 164. In the etching process, the first blocking spacer 162 may protect the first sheet pattern NS1 and the third sheet pattern NS3, and the second blocking spacer 164 may protect the second sheet pattern NS2 and the fourth sheet pattern NS4.

In semiconductor devices, an insulating film can separate gate electrodes according to circuit design. If a channel of a transistor of a semiconductor device is damaged in the process of forming the insulating film for separating the gate electrodes, electrical characteristics and reliability of the semiconductor device may be reduced. In the disclosed semiconductor devices, however, the blocking spacer 160 may be disposed on the sheet patterns NS1, NS2, NS3, and NS4 to protect the sheet patterns NS1, NS2, NS3, and NS4 in the process of forming the gate isolation insulating film 170. Accordingly, electrical characteristics and reliability of the semiconductor device can be improved. In addition, the gate electrodes 120, 220, 320, and 420 may not be disposed between the blocking spacer 160 and the sheet patterns NS1, NS2, NS3, and NS4. Accordingly, the scale of the semiconductor device may be reduced, and the integration density of the semiconductor device may be improved.

Referring to FIGS. 25 and 3, the gate isolation insulating film 170 may be formed in the gate isolation trench 170_T.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A semiconductor device, comprising:
a substrate;
a first active pattern disposed on an upper surface the substrate, wherein the first active pattern comprises a first lower pattern, and wherein a first sheet pattern is disposed on the first lower pattern;
a second active pattern disposed on the substrate and spaced apart from the first active pattern in a first direction, wherein the second active pattern comprises a second lower pattern, and wherein a second sheet pattern is disposed on the second lower pattern;
a first gate electrode disposed on the first active pattern and elongated in the first direction;
a second gate electrode disposed on the second active pattern and elongated in the first direction;
a gate isolation insulating film disposed between the first gate electrode and the second gate electrode and elongated in a second direction different from the first direction; and
a blocking spacer disposed between the gate isolation insulating film and the first gate electrode,
wherein the blocking spacer is disposed on a side surface of the first sheet pattern and a side surface of the first lower pattern and is elongated in a third direction perpendicular to the upper surface of the substrate.

2. The semiconductor device according to claim 1, wherein the gate isolation insulating film comprises a stepped portion disposed on an upper surface of the blocking spacer.

3. The semiconductor device according to claim 1, wherein a bottom surface of the blocking spacer is disposed on the upper surface of the substrate.

4. The semiconductor device according to claim 1, wherein the blocking spacer is in contact with the side surface of the first sheet pattern.

5. The semiconductor device according to claim 1, wherein the second gate electrode surrounds the second sheet pattern, and
wherein at least a portion of the second gate electrode is disposed between the gate isolation insulating film and the second sheet pattern.

6. The semiconductor device according to claim 1, wherein a bottom surface of the gate isolation insulating film is disposed on the upper surface of the substrate.

7. The semiconductor device according to claim 1, further comprising an insulating residue disposed between the blocking spacer and the gate isolation insulating film.

8. The semiconductor device according to claim 1, further comprising a gate insulating film surrounding the first sheet pattern,
wherein at least a portion of the gate insulating film extends along a side surface of the blocking spacer.

9. The semiconductor device according to claim 1, further comprising a device isolation trench defined by the upper surface of the substrate, the side surface of the first lower pattern, and a side surface of the second lower pattern,
wherein the blocking spacer is disposed on a side surface of the device isolation trench and on a bottom surface of the device isolation trench.

10. The semiconductor device according to claim 1, wherein the blocking spacer comprises a surface that is inclined relative to the substrate and connected to an upper surface of the blocking spacer.

11. A semiconductor device, comprising:
a substrate;
a first active pattern disposed on the substrate and comprising a first sheet pattern;
a second active pattern spaced apart from the first active pattern in a first direction and comprising a second sheet pattern;
a third active pattern disposed on the first active pattern and comprising a third sheet pattern;
a fourth active pattern disposed on the second active pattern and comprising a fourth sheet pattern;
a first gate electrode surrounding at least a portion of the first sheet pattern and elongated in the first direction;
a second gate electrode surrounding at least a portion of the second sheet pattern and elongated in the first direction;
a third gate electrode disposed on the first gate electrode and surrounding at least a portion of the third sheet pattern;
a fourth gate electrode disposed on the second gate electrode and surrounding at least a portion of the fourth sheet pattern;
a gate capping pattern disposed on the third gate electrode and on the fourth gate electrode;
a gate isolation insulating film disposed between the first gate electrode and the second gate electrode, and between the third gate electrode and the fourth gate electrode; and
a first blocking spacer disposed between the gate isolation insulating film and the first gate electrode, and between the gate isolation insulating film and the third gate electrode,
wherein the gate isolation insulating film is elongated in a second direction different from the first direction, and the first blocking spacer is in direct contact with a side surface of the first sheet pattern and a side surface of the third sheet pattern, respectively.

12. The semiconductor device according to claim 11, further comprising a second blocking spacer disposed between the gate isolation insulating film and the second gate electrode and between the gate isolation insulating film and the fourth gate electrode,
wherein the first blocking spacer and the second blocking spacer are spaced apart from each other by the gate isolation insulating film.

13. The semiconductor device according to claim 11, wherein at least a portion of the gate isolation insulating film is disposed on an upper surface of the first blocking spacer.

14. The semiconductor device according to claim 11, wherein a distance from an upper surface of the gate capping pattern to an upper surface of the third sheet pattern is the same as a distance from an upper surface of the gate capping pattern to an upper surface of the first blocking spacer.

15. The semiconductor device according to claim 11, wherein the gate isolation insulating film extends through the gate capping pattern.

16. The semiconductor device according to claim 11, further comprising a gate insulating film surrounding the first sheet pattern,
wherein the gate insulating film is positioned outside the space between the first sheet pattern and the first blocking spacer.

17. The semiconductor device according to claim 11, wherein the first gate electrode comprises a first material, and the third gate electrode comprises a second material different from the first material.

18. The semiconductor device according to claim 11, comprising an interlayer gate isolation film disposed between the first gate electrode and the third gate electrode, and between the second gate electrode and the fourth gate electrode.

19. The semiconductor device according to claim 11, wherein an angle between an upper surface of the substrate and a side surface of the blocking spacer is an acute angle.

20. A semiconductor device, comprising:
a substrate;
a first active pattern disposed on an upper surface of the substrate, wherein the first active pattern comprises a first lower pattern, and wherein a first sheet pattern is disposed on the first lower pattern;
a second active pattern disposed on the substrate and spaced apart from the first active pattern in a first direction, wherein the second active pattern comprises a second lower pattern, and wherein a second sheet pattern is disposed on the second lower pattern;
a third active pattern disposed on the first active pattern and comprising a third sheet pattern;
a fourth active pattern disposed on the second active pattern and comprising a fourth sheet pattern;
a first gate electrode surrounding at least a portion of the first sheet pattern and elongated in the first direction;
a second gate electrode surrounding at least a portion of the second sheet pattern and elongated in the first direction;
a third gate electrode disposed on the first gate electrode and surrounding at least a portion of the third sheet pattern;
a fourth gate electrode disposed on the second gate electrode and surrounding at least a portion of the fourth sheet pattern;
a gate capping pattern disposed on the third gate electrode and the fourth gate electrode;
a first blocking spacer disposed on a side surface of the first lower pattern, a side surface of the first sheet pattern, and a side surface of the third sheet pattern and is elongated in a second direction different from the first direction;
a second blocking spacer disposed on a side surface of the second lower pattern, a side surface of the second sheet pattern, and a side surface of the fourth sheet pattern and elongated in the second direction; and
a gate isolation insulating film disposed between the first blocking spacer and the second blocking spacer, wherein
the gate isolation insulating film comprises a stepped portion disposed on an upper surface of the first blocking spacer, and
a bottom surface of the gate isolation insulating film is disposed on an upper surface of the substrate.
